(19) United States
(12) Patent Application Publication
(10) Pub. No.: US 2024/0093372 A1
(43) Pub. Date: Mar. 21, 2024

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Tadashi TAKASAKI, Toyama-shi (JP); Atsushi Moriya, Toyama-shi (JP); Kaoru Yamamoto, Toyama-shi (JP); Naofumi Ohashi, Toyama-shi (JP)

(73) Assignee: Kokusai Electric Corporation, Tokyo (JP)

(21) Appl. No.: 18/354,220

(22) Filed: Jul. 18, 2023

(30) Foreign Application Priority Data
Sep. 15, 2022 (JP) 2022-147102

(51) Int. Cl. C23C 16/52; C23C 16/44; C23C 16/455; H01J 37/32

(52) U.S. Cl. CPC C23C 16/52; C23C 16/4405; C23C 16/4408; C23C 16/4412; C23C 16/45565; C23C 16/4557; H01J 37/32357; H01J 37/32449; H01J 37/32834; H01J 2237/3321

(57) ABSTRACT

A technique includes at least one chamber including a process chamber that is capable of processing a substrate and a shower head arranged in an upstream of the process chamber; a gas supplier that is capable of supplying a gas into the process chamber via the shower head; a first exhaust pipe communicating with the shower head; a second exhaust pipe communicating with the process chamber; a first exhaust controller installed in the first exhaust pipe; a first heater installed in the first exhaust pipe; and a controller configured to be capable of: (a) controlling the gas supplier so as to supply a processing gas as the gas to the shower head, and (b) controlling the gas supplier so as to supply a non-processing gas as the gas to the shower head.

### CROSS-REFERENCE TO RELATED APPLICATION

This application is based upon and claims the benefit of priority from Japanese Patent Application No. 2022-147102, filed on Sep. 15, 2022, the entire contents of which are incorporated herein by reference.

### TECHNICAL FIELD

The present disclosure relates to a substrate processing apparatus, a method of processing a substrate, a method of manufacturing a semiconductor device, and a recording medium.

### BACKGROUND

In a process of manufacturing a semiconductor device, as a substrate processing apparatus for performing a predetermined process on a substrate such as a wafer or the like, there may be used an apparatus having a configuration in which a gas is supplied into a processing space via a shower head and gas and is exhausted from the shower head and the processing space.

### SUMMARY

Some embodiments of the present disclosure provide a technique capable of enhancing the throughput when processing a plurality of substrates.

According to one embodiment of the present disclosure, there is provided a technique that includes at least one chamber including a process chamber that is capable of processing a substrate and a shower head arranged in an upstream of the process chamber; a gas supplier that is capable of supplying a gas into the process chamber via the shower head; a first exhaust pipe communicating with the shower head; a second exhaust pipe communicating with the process chamber; a first exhaust controller installed in the first exhaust pipe; a first heater installed in the first exhaust pipe; and a controller configured to be capable of: (a) controlling the gas supplier so as to supply a processing gas as the gas to the shower head in a state in which the substrate is present in the process chamber and the first exhaust controller such that an inside of the first exhaust pipe has a first conductance in a state in which the first heater is operated, and (b) controlling the gas supplier so as to supply a non-processing gas as the gas to the shower head in a state in which the substrate is not present in the process chamber and the first exhaust controller such that the inside of the first exhaust pipe has a second conductance smaller than the first conductance in a state in which the first heater is operated.

### BRIEF DESCRIPTION OF DRAWINGS

The accompanying drawings, which are incorporated in and constitute a part of the specification, illustrate embodiments of the present disclosure.

FIG. 1 is a schematic diagram of a horizontal cross-section of a substrate processing system according to embodiments.

FIG. 2 is a schematic diagram of a vertical cross-section of the substrate processing system according to embodiments.

FIG. 3 is a schematic configuration diagram of a substrate processing apparatus according to embodiments.

FIG. 4 is a schematic configuration diagram of a gas exhaust system of a substrate processing apparatus according to embodiments.

FIG. 5 is a flowchart showing a substrate processing process and a cleaning process according to embodiments.

FIG. 6 is a flowchart showing details of a film-forming step in FIG. 5.

FIG. 7 is a flowchart showing an atmosphere adjustment step according to embodiments.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments of the Present Disclosure

Embodiments of the present disclosure will be described below with reference to the drawings. The drawings used in the following description are all schematic. The dimensional relationship of respective elements, the ratio of respective elements, and the like shown in the drawings do not necessarily match the actual ones. In addition, the dimensional relationship of respective elements, the ratio of respective elements, and the like do not necessarily match between a plurality of drawings.

### (1) Configuration of Substrate Processing System

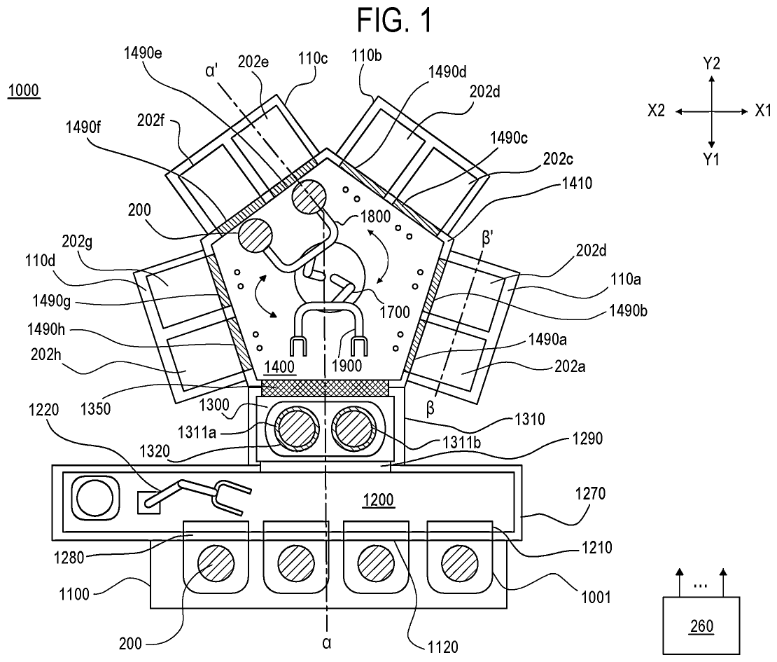

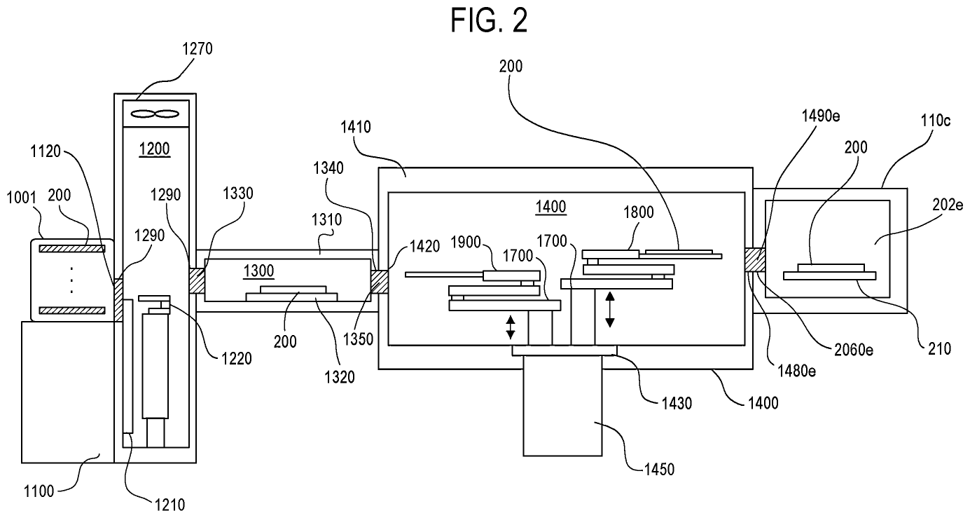

First, a substrate processing system including a substrate processing apparatus will be described. FIG. 1 is a horizontal cross-sectional view showing a configuration example of the substrate processing system according to the present embodiment. FIG. 2 is a vertical cross-sectional view taken along line α-α′ in FIG. 1, showing a configuration example of the substrate processing system according to the present embodiment.

Referring to FIGS. 1 and 2, the substrate processing system 1000 is configured to process a substrate 200 and is mainly composed of an IO stage 1100, an atmospheric transfer chamber 1200, a load lock chamber 1300, a vacuum transfer chamber 1400, and a process module 110. Next, each configuration will be specifically described. In the description of FIG. 1, it is denoted that an X1 direction is right, an X2 direction is left, an Y1 direction is front, and the Y2 direction is rear.

### (Atmospheric Transfer Chamber/IO Stage)

An IO stage (load port) 1100 is installed in front of the substrate processing system 1000. A plurality of pods 1001 are mounted on the IO stage 1100. The pod 1001 is used as a carrier for transferring substrates 200 such as silicon (Si) wafers. A plurality of unprocessed substrates (wafers) 200 or a plurality of processed substrates 200 are stored in the pod 1001 in a horizontal posture.

The pod 1001 is provided with a cap 1120, which is opened and closed by a pod opener 1210 which will be described later. The pod opener 1210 configured to open and close the cap 1120 of the pod 1001 placed on the IO stage 1100 and can load and unload the substrate 200 into and from the pod 1001 by opening and closing a substrate loading/unloading port.

The IO stage 1100 is adjacent to the atmosphere transfer chamber 1200. The load lock chamber 1300 (to be described later) is connected to the surface of the atmospheric transfer chamber 1200 which is opposite from the IO stage 1100.

An atmospheric transfer robot 1220 as a first transfer robot for transferring the substrate 200 is installed in the atmospheric transfer chamber 1200.

As shown in FIGS. 1 and 2, a substrate loading/unloading port 1280 for loading and unloading the substrate 200 into and from the atmospheric transfer chamber 1200, and a pod opener 1210 are installed on a front side of a housing 1270 of the atmospheric transfer chamber 1200. The IO stage (load port) 1100 is installed on the side opposite to the pod opener 1210 across the substrate loading/unloading port 1280, that is, on the outside of the housing 1270.

A substrate loading/unloading port 1290 for loading and unloading the substrate 200 into and from the load lock chamber 1300 is provided on the rear side of the housing 1270 of the atmospheric transfer chamber 1200. The substrate loading/unloading port 1290 is opened and closed by a gate valve 1330 which will be described later, which makes it possible to load and unload the substrate 200.

### (Load Lock (L/L) Chamber)

The load lock chamber 1300 is adjacent to the atmospheric transfer chamber 1200. As will be described later, a vacuum transfer chamber 1400 is arranged on the surface of the housing 1310 constituting the load lock chamber 1300 which is opposite from the atmospheric transfer chamber 1200.

A substrate loading/unloading port 1340 is provided on the side of the housing 1310 adjacent to the vacuum transfer chamber 1400. The substrate loading/unloading port 1340 is opened/closed by a gate valve 1350, which makes it possible to load and unload the substrate 200.

Further, a substrate mounting table 1320 having at least two mounting surfaces 1311 (1311a and 1311b) on which the substrate 200 is mounted is installed in the load lock chamber 1300. The distance between the substrate mounting surfaces 1311 is set according to the distance between fingers of a vacuum transfer robot 1700, which will be described later.

### (Vacuum Transfer Chamber)

The substrate processing system 1000 includes a vacuum transfer chamber (transfer module) 1400 as a transfer chamber serving as a transfer space in which the substrate 200 is transferred at a negative pressure. The housing 1410 constituting the vacuum transfer chamber 1400 is formed in a shape of a pentagon when viewed from above, and the load lock chamber 1300 and the process modules 110a to 110d for processing the substrate 200 are connected to the respective sides of the pentagon. A vacuum transfer robot 1700 serving as a second transfer robot that transfers the substrate 200 at a negative pressure is installed at substantially the center of the vacuum transfer chamber 1400 using a flange 1430 as a base.

A substrate loading/unloading port 1420 is provided at a side wall of the housing 1410 adjacent to the load lock chamber 1300. The substrate loading/unloading port 1420 is opened and closed by a gate valve 1350, which makes it possible to load and unload the substrate 200.

As shown in FIG. 2, the vacuum transfer robot 1700 installed in the vacuum transfer chamber 1400 is configured to be moved up and down by means of an elevator 1450 and a flange 1430 while maintaining the airtightness of the vacuum transfer chamber 1400. The elevator 1450 is configured to independently raise and lower two arms 1800 and 1900 of the vacuum transfer robot 1700. The arm 1800 and the arm 1900 are bifurcated, and are capable of loading and unloading the substrates into and from two chambers 202 in the process module 110, which will be described later.

The vacuum transfer robot 1700 transfers the substrate 200 between each process module 110 and the load lock chamber 1300. FIG. 2 shows an example of mounting the substrate 200 unloaded from the process module 110c.

### (Process Module)

As shown in FIG. 1, process modules 110a, 110b, 110c, and 110d, which perform desired processing on the substrate 200, are connected to the side walls where the load lock chamber 1300 is not installed, among the five side walls of the housing 1410. Hereinafter, these modules may be collectively referred to as process modules 110.

Each of the process modules 110a, 110b, 110c, and 110d is provided with chambers 202, which are one configuration of the substrate processing apparatus. Specifically, chambers 202a and 202b are installed in the process module 110a. Chambers 202c and 202d are installed in the process module 110b. Chambers 202e and 202f are installed in the process module 110c. Chambers 202g and 202h are installed in the process module 110d.

A substrate loading/unloading port 1480 is provided in the side wall of the housing 1410 facing each chamber 202. For example, as shown in FIG. 2, a substrate loading/unloading port 1480e is provided in the side wall facing the chamber 202e.

If the chamber 202e is replaced with the chamber 202a in FIG. 2, a substrate loading/unloading port 1480a is provided on the side wall facing the chamber 202a.

Similarly, when the chamber 202f is replaced with the chamber 202b, a substrate loading/unloading port 1480b is provided in the side wall facing the chamber 202b.

A gate valve 1490 is provided for each process chamber as shown in FIG. 1. Specifically, a gate valve 1490a is provided between the chamber 202a and the vacuum transfer chamber 1400, and a gate valve 1490b is provided between the chamber 202b and the vacuum transfer chamber 1400. A gate valve 1490c is provided between the chamber 202c and the vacuum transfer chamber 1400, and a gate valve 1490d is provided between the chamber 202d and the vacuum transfer chamber 1400. A gate valve 1490e is provided between the chamber 202e and the vacuum transfer chamber 1400, and a gate valve 1490f is provided between the chamber 202f and the vacuum transfer chamber 1400. A gate valve 1490g is provided between the chamber 202g and the vacuum transfer chamber 1400, and a gate valve 1490h is provided between the chamber 202h and the vacuum transfer chamber 1400.

By opening and closing each gate valve 1490, the substrate 200 can be loaded and unloaded through the substrate loading/unloading port 1480.

### (2) Configuration of Substrate Processing Apparatus

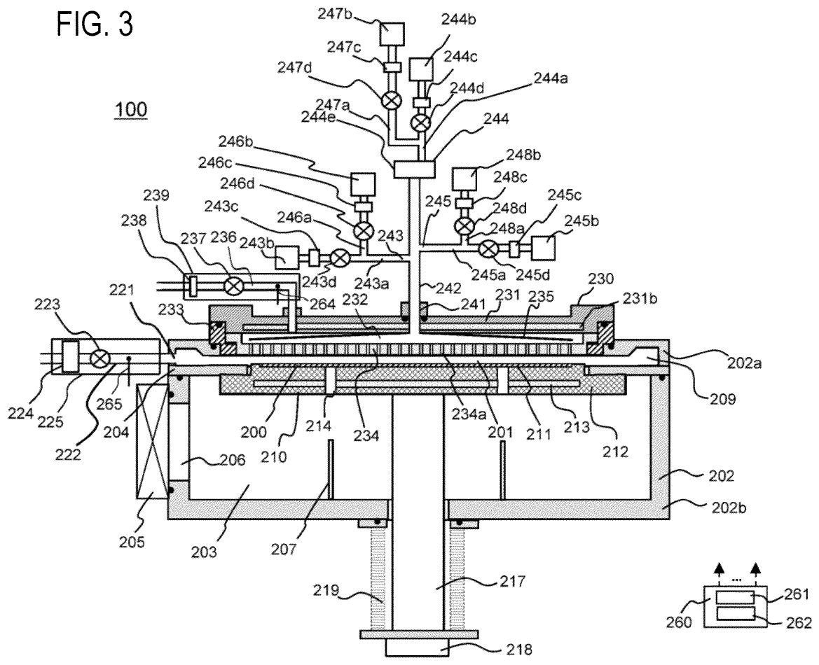

Next, a substrate processing apparatus, which is one component of the substrate processing system 1000, will be described. In the following descriptions, a single-substrate-type substrate processing apparatus that processes substrates 200 to be processed one by one will be described as an example of the substrate processing apparatus. FIG. 3 is a schematic configuration diagram of a single-substrate-type substrate processing apparatus according to the present embodiment.

### (Chamber)

As shown in FIG. 3, the substrate processing apparatus 100 includes a chamber 202 as a process container. The chamber 202 corresponds to the chambers 202a, 202b, 202c, 202d, 202e, 202f, 202g and 202h in the substrate processing system 1000 having the configuration described above. That is, each chamber 202 may be configured similarly.

The chamber 202 is configured as, for example, a flat closed container having a circular cross section. Further, the chamber 202 is made of a metal material such as aluminum (Al) or stainless steel (SUS). A process chamber 201, which is a processing space for processing a substrate 200 such as a silicon wafer, and a transfer space 203 through which the substrate 200 passes when transferring the substrate 200 to the process chamber 201 are formed in the chamber 202. That is, the chamber 202 includes at least the process chamber 201 capable of processing the substrate.

The chamber 202 is composed of an upper container 202a and a lower container 202b. A partition plate 204 is provided between the upper container 202a and the lower container 202b.

An exhaust buffer chamber 209 is installed in the vicinity of the outer peripheral edge inside the upper container 202a. The exhaust buffer chamber 209 functions as a buffer space when the gas inside the process chamber 201 is exhausted laterally. Therefore, the exhaust buffer chamber 209 has a space surrounding the lateral periphery of the process chamber 201. In other words, the exhaust buffer chamber 209 has a space having a ring-shape (annular shape) in a plan view on the outer peripheral side of the process chamber 201. The space of the exhaust buffer chamber 209 is formed such that its ceiling surface and both side wall surfaces is formed by the upper container 202a and its floor surface is formed by the partition plate 204. The inner peripheral side of the space communicates with the process chamber 201, and it is configured to introduce the gas supplied into the process chamber 201 into the exhaust buffer chamber 209 through the communicating portion.

A substrate loading/unloading port 206 adjacent to a gate valve 205 is provided on the side surface of the lower container 202b, and the substrate 200 is moved to and from the vacuum transfer chamber 1400 through the substrate loading/unloading port 206. A plurality of lift pins 207 are provided at the bottom of the lower container 202b.

### (Substrate Support)

A substrate support 210 that supports the substrate 200 is installed in the process chamber 201. The substrate support 210 mainly includes a substrate mounting surface 211 on which the substrate 200 is mounted, a substrate mounting table 212 having the substrate mounting surface 211 on its front surface, and a heater 213 as a third heater built in the substrate mounting table 212. Through-holes 214 through which the lift pins 207 pass are provided in the substrate mounting table 212 at positions corresponding to the lift pins 207.

The substrate mounting table 212 is supported by a shaft 217. The shaft 217 passes through the bottom of the chamber 202 and is connected to an elevating mechanism 218 outside the chamber 202. By operating the elevating mechanism 218 to raise and lower the shaft 217 and the substrate mounting table 212, it is possible to raise and lower the substrate 200 mounted on the substrate mounting surface 211. The circumference of the lower end portion of the shaft 217 is covered with a bellows 219, and the inside of the chamber 202 is kept airtight.

When transferring the substrate 200, the substrate mounting table 212 is lowered to a position (wafer transfer position) where the substrate mounting surface 211 faces the substrate loading/unloading port 206. When processing the substrate 200, the substrate mounting table 212 is raised until the substrate 200 reaches the processing position (wafer processing position) in the process chamber 201. Specifically, when the substrate mounting table 212 is lowered to the wafer transfer position, the upper ends of the lift pins 207 protrude from the upper surface of the substrate mounting surface 211 so that the lift pins 207 support the substrate 200 from below. Further, when the substrate mounting table 212 is raised to the wafer processing position, the lift pins 207 are retracted from the upper surface of the substrate mounting surface 211 so that the substrate mounting surface 211 supports the substrate 200 from below. Since the lift pins 207 are in direct contact with the substrate 200, it is desirable that the lift pins 207 are made of a material such as quartz or alumina.

### (Shower Head)

A shower head 230 as a gas dispersion mechanism is installed in the upper portion of the process chamber 201 (on the upstream side in the gas supply direction). In other words, the chamber 202 includes the process chamber 201 and the shower head 230 provided above the process chamber 201. A lid 231 of the shower head 230 is provided with a gas introduction port 241, and a gas supply system described later is connected to the gas introduction port 241. A gas introduced from the gas introduction port 241 is supplied to a shower head buffer chamber 232 which is a space formed within the shower head 230.

A support block 233 for supporting the lid 231 of the shower head 230 is provided between the lid 231 and the upper container 202a.

The shower head 230 includes a distribution plate 234 for dispersing the gas supplied from the gas supply system through the gas introduction port 241. The upstream side of the dispersion plate 234 is the shower head buffer chamber 232, and the downstream side thereof is the process chamber 201. The dispersion plate 234 is provided with a plurality of through-holes 234a. The dispersion plate 234 is arranged above the substrate mounting surface 211 so as to face the substrate mounting surface 211. Therefore, the shower head buffer chamber 232 communicates with the process chamber 201 through the through-holes 234a installed in the dispersion plate 234.

The shower head buffer chamber 232 is provided with a gas guide 235 that forms a flow of the supplied gas. The gas guide 235 has a conical shape such that the diameter thereof increases toward the dispersion plate 234 from the gas introduction port 241 as an apex. The gas guide 235 is formed so that the lower end thereof is located more outward than the through-holes 234a formed on the outermost side of the dispersion plate 234. That is, the shower head buffer chamber 232 includes the gas guide 235 that guides the gas supplied from above the dispersion plate 234 toward the process chamber 201.

The shower head 230 may include a heater 231b as a heat source for increasing the temperature of the shower head buffer chamber 232 and the process chamber 201.

### (Gas Supply System)

A common gas supply pipe 242 is connected to a gas introduction hole 241 provided in the lid 231 of the shower head 230. The common gas supply pipe 242 communicates with the shower head buffer chamber 232 in the shower head 230 by being connected to the gas introduction hole 241. Further, a first gas supply pipe 243a, a second gas supply pipe 244a, and a third gas supply pipe 245a are connected to the common gas supply pipe 242. The second gas supply pipe 244a is connected to the common gas supply pipe 242 via a remote plasma unit (RPU) 244e.

Among them, a precursor gas is mainly supplied from the precursor gas supply system 243 including the first gas supply pipe 243a, and a reaction gas is mainly supplied from a reaction gas supply system 244 including the second gas supply pipe 244a. The precursor gas and the reaction gas function as processing gases for processing the substrate 200. Either or both of an inert gas and a cleaning gas are supplied from an inert gas supply system 245 including the third gas supply pipe 245a. The inert gas and the cleaning gas function as non-processing gases that do not perform a process on the substrate 200.

Thus, there is provided a gas supply system as a gas supplier capable of supplying various gases to the process chamber 201 through the shower head 230.

As for the gases supplied to the shower head buffer chamber 232 of the shower head 230 through the common gas supply pipe 242, the precursor gas is sometimes referred to as a first gas, the reaction gas is sometimes referred to as a second gas, the inert gas is sometimes referred to as a third gas, and the cleaning gas is sometimes referred to as a fourth gas.

### (Precursor Gas Supply System)

In the first gas supply pipe 243a, a precursor gas supply source 243b, a mass flow controller (MFC) 243c as a flow rate controller (flow rate control part), and a valve 243d as an opening/closing valve are installed sequentially from the upstream side. The precursor gas, which is the first gas, is supplied from the first gas supply pipe 243a into the shower head buffer chamber 232 via the MFC 243c, the valve 243d, and the common gas supply pipe 242.

The precursor gas is one of the processing gases, and is, for example, a Si₂Cl₆ (disilicon hexachloride or hexachlorodisilane) gas that is a precursor containing a Si (silicon) element. The precursor gas is also called a Si-containing gas. The precursor gas may be solid, liquid, or gaseous at a room temperature and an atmospheric pressure. If the precursor gas is liquid at the room temperature and the atmospheric pressure, a vaporizer (not shown) may be provided between the first gas supply source 243b and the MFC 243c. Here, the precursor gas is described as a gas.

A precursor gas supply system 243 is mainly composed of the first gas supply pipe 243a, the MFC 243c, and the valve 243d. The precursor gas supply system 243 may include the precursor gas supply source 243b and the first inert gas supply system described later. Since the precursor gas supply system 243 supplies a precursor gas which is one of the processing gases, it corresponds to one of the processing gas supply systems.

The downstream end of a first inert gas supply pipe 246a is connected to the first gas supply pipe 243a on the downstream side of the valve 243d. In the first inert gas supply pipe 246a, an inert gas supply source 246b, an MFC 246c as a flow rate controller (flow rate control part), and a valve 246d as an opening/closing valve are installed sequentially from the upstream side. The inert gas is supplied from the first inert gas supply pipe 246a into the shower head buffer chamber 232 via the MFC 246c, the valve 246d and the first gas supply pipe 243a.

Since the inert gas acts as a carrier gas for the precursor gas, it is desirable that a gas that does not react with a precursor is used as the inert gas. Specifically, for example, a nitrogen (N₂) gas may be used as the inert gas. In addition to the N₂ gas, rare gases such as a helium (He) gas, a neon (Ne) gas, and an argon (Ar) gas may be used as the inert gas.

A first inert gas supply system is mainly composed of the first inert gas supply pipe 246a, the MFC 246c, and the valve 246d. The first inert gas supply system may include the inert gas supply source 246b and the first gas supply pipe 243a. In addition, the first inert gas supply system may be included in the precursor gas supply system 243.

### (Reaction Gas Supply System)

An RPU 244e is installed in the downstream region of the second gas supply pipe 244a. In the upstream region of the second gas supply pipe 244a, a reaction gas supply source 244b, an MFC 244c as a flow rate controller (flow rate control part), and a valve 244d as an opening/closing valve are installed sequentially from the upstream side. The reaction gas, which is the second gas, is supplied from the second gas supply pipe 244a into the shower head buffer chamber 232 via the MFC 244c, the valve 244d, the RPU 244e, and the common gas supply pipe 242. The reaction gas is brought into a plasma state by the remote plasma unit 244e and is irradiated onto the substrate 200 in the process chamber 201 through the plurality of through-holes 234a provided in the dispersion plate 234.

The reaction gas is one of the processing gases. For example, an ammonia (NH₃) gas is used as the reaction gas. The reaction gas is a gas that reacts with the components constituting the precursor gas.

A reaction gas supply system 244 is mainly composed of the second gas supply pipe 244a, the MFC 244c, and the valve 244d. The reaction gas supply system 244 may include the reaction gas supply source 244b, the RPU 244e, and the second inert gas supply system described later. Since the reaction gas supply system 244 supplies the reaction gas, which is one of the process gases, it corresponds to another one of the processing gas supply systems.

The downstream end of a second inert gas supply pipe 247a is connected to the second gas supply pipe 244a on the downstream side of the valve 244d. In the second inert gas supply pipe 247a, an inert gas supply source 247b, an MFC 247c as a flow rate controller (flow rate control part), and a valve 247d as an opening/closing valve are installed sequentially from the upstream side. The inert gas is supplied from the second inert gas supply pipe 247a into the shower head buffer chamber 232 via the MFC 247c, the valve 247d, the second gas supply pipe 244a, and the RPU 244e.

The inert gas is a gas that acts as a carrier gas or a dilution gas of the reaction gas. Specifically, for example, a N₂ gas may be used as the inert gas. In addition to the N₂ gas, rare gases such as a He gas, a Ne gas, and an Ar gas may be used as the inert gas.

A second inert gas supply system is mainly composed of the second inert gas supply pipe 247a, the MFC 247c, and the valve 247d. The second inert gas supply system may include the inert gas supply source 247b, the second gas supply pipe 243a, and the RPU 244e. In addition, the second inert gas supply system may be included in the reaction gas supply system 244.

### (Inert Gas Supply System)

In the third gas supply pipe 245a, an inert gas supply source 245b, an MFC 245c as a flow rate controller (a flow rate control part), and a valve 245d as an opening/closing valve are installed sequentially from the upstream side. The inert gas as a purge gas is supplied from the third gas supply pipe 245a into the shower head buffer chamber 232 via the MFC 245c, the valve 245d, and the common gas supply pipe 242 in the film-forming step to be described later. In addition, in the first cleaning step to be described later, the inert gas as a carrier gas or a dilution gas of the cleaning gas is supplied into the shower head buffer chamber 232 via the MFC 245c, the valve 245d, and the common gas supply pipe 242, if necessary.

The inert gas supplied from the inert gas supply source 245b is one of the non-processing gases, and acts as a purge gas for purging the gases remaining in the chamber 202 and the shower head 230 in the film-forming step. The inert gas may also act as a carrier gas or dilution gas of the cleaning gas in the first cleaning step. Specifically, for example, a N₂ gas may be used as the inert gas. In addition to the N₂ gas, rare gases such as a He gas, a Ne gas, and an Ar gas may also be used as the inert gas.

An inert gas supply system 245 is mainly composed of the third gas supply pipe 245a, the MFC 245c, and the valve 245d. The inert gas supply system 245 may include the inert gas supply source 245b.

### (Cleaning Gas Supply System)

The downstream end of a cleaning gas supply pipe 248a is connected to the third gas supply pipe 245a on the downstream side of the valve 245d. In the cleaning gas supply pipe 248a, a cleaning gas supply source 248b, an MFC 248c as a flow rate controller (flow rate control part), and a valve 248d as an opening/closing valve are installed sequentially from the upstream side. A cleaning gas is supplied from the third gas supply pipe 245a into the shower head buffer chamber 232 via the MFC 248c, the valve 248d, and the common gas supply pipe 242 in the first cleaning step.

The cleaning gas supplied from the cleaning gas supply source 248b is one of the non-processing gases, and acts as a cleaning gas for removing byproducts and the like adhering to the shower head 230 and the chamber 202 in the first cleaning step. Specifically, a fluorine-containing gas containing fluorine (F) is used as the cleaning gas. For example, a nitrogen trifluoride (NF₃) gas may be used as the cleaning gas. Further, for example, a hydrogen fluoride (HF) gas, a chlorine trifluoride gas (ClF₃) gas, a fluorine (F₂) gas, or a combination thereof may be used as the cleaning gas.

A cleaning gas supply system is mainly composed of the cleaning gas supply pipe 248a, the MFC 248c, and the valve 248d. The cleaning gas supply system may include the cleaning gas supply source 248b and the third gas supply pipe 245a.

### (Gas Exhaust System)

An exhaust system for exhausting the atmosphere in the chamber 202 includes a plurality of exhaust pipes connected to the chamber 202. Specifically, the exhaust system includes a basic exhaust pipe (not shown) connected to the transfer space 203 of the lower container 202b, a first exhaust pipe 236 connected to the shower head buffer chamber 232 of the shower head 230 and communicating with the shower head 230, and a second exhaust pipe 222 connected to the exhaust buffer chamber 209 of the upper container 202a and communicating with the process chamber 201.

### (First Gas Exhaust System)

A first exhaust pipe 236 is connected to the upper surface or the side surface of the shower head buffer chamber 232. That is, the first exhaust pipe 236 is connected to the shower head 230 to thereby communicate with the shower head buffer chamber 232 in the shower head 230.

A first valve 237 is installed in the first exhaust pipe 236. Furthermore, a vacuum pump 253, which will be described later, is installed in the first exhaust pipe 236 on the downstream side of the first valve 237. The vacuum pump 253 exhausts the atmosphere in the shower head buffer chamber 232 through the first exhaust pipe 236. This exhaust is controlled by the first valve 237. That is, the first valve 237 functioning as a first exhaust controller that is capable of controlling the exhaust through the first exhaust pipe 236 is installed in the first exhaust pipe 236. In the first exhaust pipe 236, an APC (Auto Pressure Controller) 238, which is a pressure controller for controlling the internal pressure of the shower head buffer chamber 232 to a predetermined pressure, may be installed between the vacuum pump 253 and the first valve 237. In this case, the APC 238 may be included in the first exhaust controller.

A first gas exhaust system is mainly composed of the first exhaust pipe 236 and the first valve 237. The APC 238 may be included in the first gas exhaust system.

A first heater 239 is installed in the first exhaust pipe 236. As the first heater 239, for example, a pipe heater arranged so as to wrap around the first exhaust pipe 236 and configured to heat the inside of the first exhaust pipe 236 by supplying a power may be used.

Furthermore, in addition to the first heater 239, a temperature measurer 264 that is capable of measuring the internal temperature of the first exhaust pipe 236 may be installed in the first exhaust pipe 236. As the temperature measurer 264, for example, a temperature sensor arranged inside the first exhaust pipe 236 may be used.

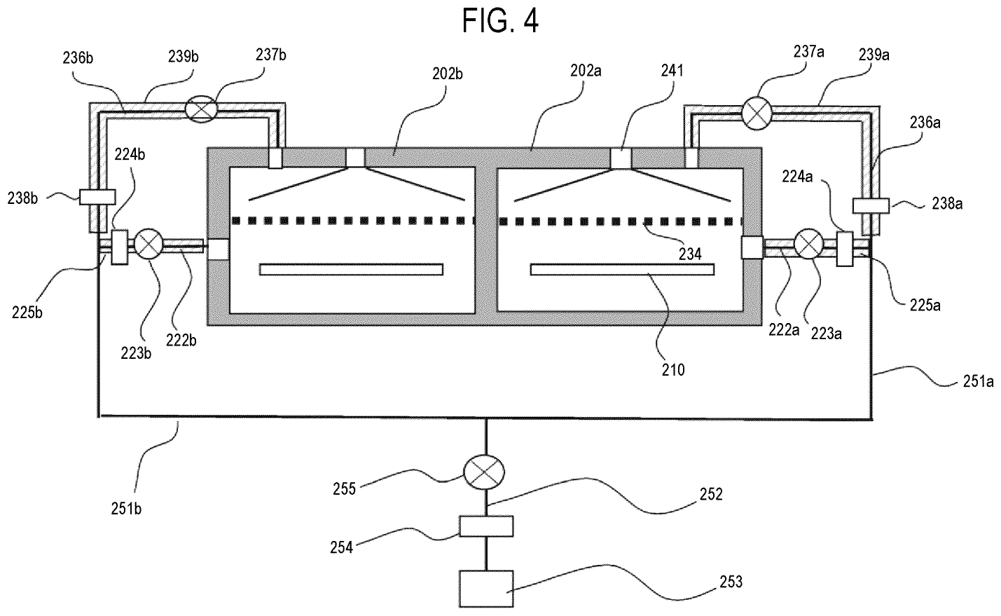

When there is a plurality of chambers 202 (202a, 202b, 202c, 202d, 202e, 202f, 202g, and 202h) in the substrate processing system 1000, each of the chamber 202 includes the first exhaust pipe 236 as shown in FIG. 4 which will be described later.

### (Second Gas Exhaust System)

The second exhaust pipe 222 is connected to the inside of the exhaust buffer chamber 209 via an exhaust-hole 221 provided on the upper surface or the lateral side of the exhaust buffer chamber 209. That is, the second exhaust pipe 222 is connected to the exhaust buffer chamber 209 so as to communicate with the process chamber 201 through the exhaust buffer chamber 209.

A second valve 223 is installed in the second exhaust pipe 222. Further, in the second exhaust pipe 222, an APC 224 as a pressure controller for controlling the internal pressure of the process chamber 201 communicating with the exhaust buffer chamber 209 to a predetermined pressure is installed on the downstream side of the second valve 223. Furthermore, in the second exhaust pipe 222, a vacuum pump 253, which will be described later, is installed on the downstream side of the APC 224. The vacuum pump 253 exhausts the atmosphere in the exhaust buffer chamber 209 and the process chamber 201 communicating therewith through the second exhaust pipe 222. This exhaust is controlled by the APC 224 and the second valve 223. That is, the APC 224 and the second valve 223 that function as a second exhaust controller capable of controlling the exhaust through the second exhaust pipe 222 are installed in the second exhaust pipe 222.

A second gas exhaust system is mainly composed of the second exhaust pipe 222, the second valve 223, and the APC 224.

A second heater 225 is installed in the second exhaust pipe 222. The second heater 225 can be used as a pipe heater, just like the first heater 239. Furthermore, a temperature measurer 265 that is capable of measuring the internal temperature of the second exhaust pipe 222 may be installed in the second exhaust pipe 222.

When there is a plurality of chambers 202 (202a, 202b, 202c, 202d, 202e, 202f, 202g, and 202h) in the substrate processing system 1000, each of the chambers 202 includes the second exhaust pipe 222 as shown in FIG. 4 which will be described later.

### (Common Exhaust System for a Plurality of Chambers)

Next, an exhaust system of a plurality of chambers 202 will be described. Here, as the plurality of chambers 202, chambers 202a and 202b are described as an example. FIG. 4 is a schematic configuration diagram of the gas exhaust system of the substrate processing apparatus according to the present embodiment.

A junction pipe 251a for joining the first exhaust pipe 236a and the second exhaust pipe 222a is connected to the downstream side portions of the first exhaust pipe 236a and the second exhaust pipe 222a extending from the chamber 202a. A junction pipe 251b for joining the first exhaust pipe 236b and the second exhaust pipe 222b is connected to the downstream side portions of the first exhaust pipe 236b and the second exhaust pipe 222b extending from the chamber 202b. A common exhaust pipe 252 is connected to the downstream side portions of the junction pipes 251a and 251b. In other words, the common exhaust pipe 252 is arranged in the downstream portions of the first exhaust pipes 236a and 236b and the second exhaust pipes 222a and 222b so as to join the first exhaust pipes 236a and 236b and the second exhaust pipes 222a and 222b.

A vacuum pump 253 is arranged in the downstream portion of the common exhaust pipe 252. An APC 254 and a valve 255 are installed sequentially from the downstream side between the vacuum pump 253 and the junction of the junction pipes 251a and 251b. The APC 254, the valve 255, the junction pipes 251a and 251b, and the common exhaust pipe 252 constitute a common exhaust system of the plurality of chambers 202a and 202b. Thus, the atmosphere in the chamber 202a and the atmosphere in the chamber 202b are exhausted by one vacuum pump 253.

Although the common exhaust system of the chambers 202a and 202b is described as an example, it is assumed that other chambers 202c, 202d, 202e, 202f, 202g and 202h have the same configuration.

### (Controller)

The substrate processing apparatus 100 includes a controller 260 that functions as a control part (control means) configured to control the operation of each part of the substrate processing apparatus 100.

The controller 260 includes at least a calculator 261 and a memory 262. The controller 260 is connected to the respective components described above. The controller 260 calls up a program and a recipe from the memory 262 in response to instructions from the host controller and the user, and controls the operations of the respective components according to the contents of the instructions. Specifically, the controller 260 controls the operations of the gate valve 205, the elevating mechanism 218, the heaters 213 and 231b, a high-frequency power source, a matcher, the MFCs 243c to 248c, the valves 243d to 248d, the APCs 224 and 238, the vacuum pump 253, the first valve 237, the second valve 223, and the like.

The controller 260 may be configured as a dedicated computer, or may be configured as a general-purpose computer. For example, an external memory device (e.g., a magnetic tape, a magnetic disk such as a flexible disk or a hard disk, an optical disk such as a CD or a DVD, a magneto-optical disk such as an MO or the like, or a semiconductor memory such as a USB memory or a memory card) memory) for storing the above program may be prepared, and the program may be installed in a general-purpose computer using the external memory device to install the program in a general-purpose computer, thereby providing the controller 260 according to the present embodiment.

Moreover, the means for supplying the program to the computer is not limited to supplying the program via the external memory device. For example, the program may be supplied using communication means such as the Internet or a dedicated line, without having to use the external memory device. That is, the program may be provided by a computer-readable recording medium that records the program. The memory 262 and the external memory device are configured as computer-readable recording media. Hereinafter, the memory 262 and the external memory device are collectively and simply referred to as a recording medium. As used herein, the term “recording medium” may include only the memory 262, only the external memory device, or both.

### (3) Substrate Processing Process

Next, a process of forming a thin film on the substrate 200 using the substrate processing apparatus 100 configured as described above will be described as a process of a method of manufacturing a semiconductor device. In the following descriptions, the controller 260 controls the operations of the respective components of the substrate processing apparatus 100.

As used herein, the term “substrate” may mean “a substrate itself,” or “a stacked body (aggregate) of a substrate and a predetermined layer or film formed on a surface of the substrate (i.e., a substrate including a predetermined layer or film formed on a surface of the substrate).” In addition, as used herein, the term “substrate surface” may mean “a surface (exposed surface) of a substrate itself,” or “a surface of a predetermined layer or film formed on a substrate, i.e., “the outermost surface of a substrate as a stacked body.”

Therefore, as used herein, the expression “a predetermined gas is supplied to a substrate” may mean “a predetermined gas is directly supplied to a surface (exposed surface) of a substrate itself,” or “a predetermined gas is supplied to a layer or film formed on a substrate, that is, the outermost surface of a substrate as a stacked body.” Further, as used herein, the expression “a layer or film is formed on a substrate” may mean “a predetermined layer or film is formed on a substrate itself, that is, a predetermined layer or film is formed on the outermost surface of a substrate as a stacked body.”

As used herein, the word “wafer” is synonymous with the word “substrate.” In that case, in the above descriptions, “substrate” may be replaced with “wafer.”

The substrate processing process will be described below. Descriptions will be made on an example where a SiN (silicon nitride) film as a silicon-containing film is formed on a substrate 200 by an alternate supply method in which a Si₂Cl₆ gas is used as a precursor gas (first processing gas) and an NH₃ gas is used as a reaction gas (second processing gas).

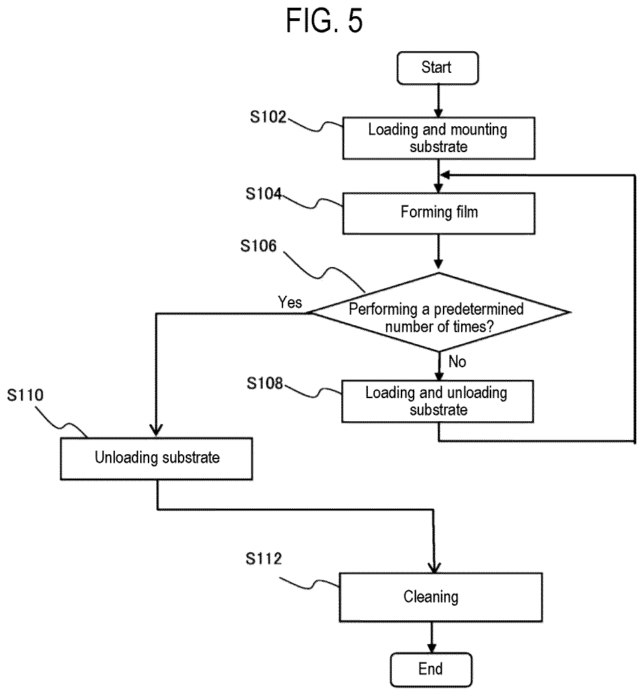

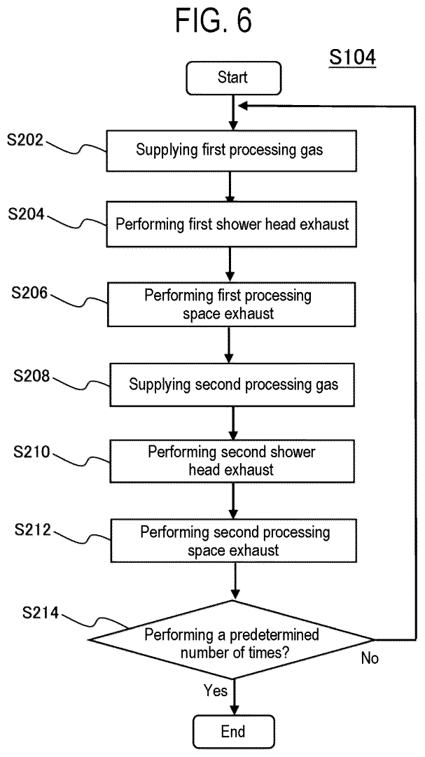

FIG. 5 is a flowchart showing a substrate processing process and a cleaning process according to the present embodiment. FIG. 6 is a flowchart showing details of the film-forming step of FIG. 5.

### (Substrate Loading/Mounting Step: S102)

In the substrate processing process, first, the substrate 200 is loaded into the process chamber 201. Specifically, the substrate mounting table 212 is lowered by the elevating mechanism 218 so that the lift pins 207 protrude from the through-holes 214 toward the upper surface of the substrate mounting table 212. After adjusting the internal pressure of the process chamber 201 to a predetermined pressure, the gate valve 205 is opened and the substrate 200 is mounted on the lift pins 207 from the gate valve 205. After mounting the substrate 200 on the lift pins 207, the substrate mounting table 212 is raised to a predetermined position by the elevating mechanism 218, whereby the substrate 200 is moved from the lift pins 207 onto the substrate mounting surface 211 of the substrate mounting table 212.

When the substrate 200 is loaded into the chamber 202, subsequently, the inside of the process chamber 201 is exhausted through the second exhaust pipe 222 such that the internal pressure of the process chamber 201 becomes a predetermined pressure (degree of vacuum). At this time, the valve opening degree of the APC 224 is feedback-controlled based on the pressure value measured by the pressure sensor. Further, an amount of supplying a power to the heater 213 is feedback-controlled based on the temperature value detected by the temperature sensor (not shown), so that the internal temperature of the process chamber 201 reaches a predetermined temperature. Specifically, the substrate mounting table 212 is heated in advance by the heater 213, and is left for a certain period of time after the temperature change of the substrate 200 or the substrate mounting table 212 disappears.

### (Film-Forming Step: S104)

After the substrate loading/mounting step S102, subsequently, a film-forming step S104 is performed. The film-forming step S104 will be described in detail below with reference to FIG. 6. The film-forming step S104 is a cyclic process in which steps of alternately supplying different processing gases are repeated.

### (First Processing Gas Supply Step: S202)

In the film-forming step S104, first, a first processing gas (precursor gas) supply step S202 is performed.

When supplying the precursor gas (e.g., Si₂Cl₆ gas) which is the first processing gas, the valve 243d is opened and the MFC 243c is adjusted such that the flow rate of the precursor gas becomes a predetermined flow rate. As a result, the supply of the precursor gas into the process chamber 201 is started. The supply flow rate of the precursor gas is, for example, 100 to 500 sccm. The precursor gas is dispersed by the shower head 230 and uniformly supplied onto the substrate 200 in the process chamber 201.

That is, in the first processing gas supply step S202, the precursor gas supply system 243 supplies the precursor gas, which is one of the processing gases, to the shower head 230 while the substrate 200 is in the process chamber 201.

At this time, the valve 246d of the first inert gas supply system is opened to supply an inert gas (N₂ gas) from the first inert gas supply pipe 246a. The supply flow rate of the inert gas is, for example, 500 to 5000 sccm. The inert gas may be supplied from the third gas supply pipe 245a of the inert gas supply system 245.

An excess precursor gas is uniformly introduced into the exhaust buffer chamber 209 from the process chamber 201, flows through the second exhaust pipe 222 of the second gas exhaust system, and is exhausted. Specifically, the second valve 223 in the second gas exhaust system is opened, and the internal pressure of the process chamber 201 is controlled to a predetermined pressure by the APC 224. All valves of the exhaust system other than the second valve 223 in the second gas exhaust system are closed.

After a predetermined time has elapsed since the start of supply of the precursor gas, the valve 243d in the precursor gas supply system 243 is closed to stop the supply of the precursor gas. The supply time of the precursor gas and the carrier gas is, for example, 2 to 20 seconds.

### (First Shower Head Exhaust Step: S204)

After stopping the supply of the precursor gas, an inert gas (N₂ gas) is supplied from the third gas supply pipe 245a to purge the inside of the shower head buffer chamber 232. At this time, among the valves of the gas exhaust system, the second valve 223 in the second gas exhaust system is closed, while the first valve 237 in the first gas exhaust system is opened. Other valves of the gas exhaust system remain closed. That is, when purging the inside of the shower head buffer chamber 232, the exhaust buffer chamber 209 is cut off from the APC 224 to stop the pressure control by the APC 224, while allowing the shower head buffer chamber 232 to communicate with the vacuum pump 253. As a result, the precursor gas remaining in the shower head 230 (shower head buffer chamber 232) is exhausted from the shower head buffer chamber 232 via the first exhaust pipe 236 by the vacuum pump 253. At this time, the valve on the downstream side of the APC 224 may be opened.

The supply flow rate of the inert gas (N₂ gas) in the first shower head exhaust step S204 is, for example, 1000 to 10000 sccm. In addition, the supply time of the inert gas is, for example, 2 to 10 seconds.

At this time, the internal temperature of the first exhaust pipe 236 for exhausting the remaining precursor gas is controlled by operating the first heater 239. Specifically, the first heater 239 is controlled so that the internal temperature of the first exhaust pipe 236 reaches a temperature that does not promote thermal decomposition of the precursor gas. By setting the internal temperature of the first exhaust pipe 236 to a temperature that does not promote thermal decomposition in this way, it is possible to suppress adhesion of the precursor gas to the inside of the first exhaust pipe 236.

As for the exhaust through the first exhaust pipe 236, the conductance during the exhaust is adjusted by the first valve 237. Specifically, the first valve 237 is controlled so that the first exhaust pipe 236 has the first conductance. At this time, the APC 238 may be used for control. Details of the first conductance will be described later.

### (First Processing Space Exhaust Step: S206)

After purging the inside of the shower head buffer chamber 232, the process chamber 201 is purged by supplying an inert gas (N₂ gas) from the third gas supply pipe 245a. At this time, the second valve 223 in the second gas exhaust system is opened, and the internal pressure of the process chamber 201 is controlled to a predetermined pressure by the APC 224. On the other hand, all the valves of the gas exhaust system other than the second valve 223 are closed. As a result, the precursor gas that has not been adsorbed onto the substrate 200 in the first processing gas supply step S202 is removed from the process chamber 201 by the vacuum pump 253 via the second exhaust pipe 222 and the exhaust buffer chamber 209.

The supply flow rate of the inert gas (N₂ gas) in the first processing space exhaust step S206 is, for example, 1,000 to 10,000 sccm. In addition, the supply time of the inert gas is, for example, 2 to 10 seconds.

Although the first processing space exhaust step S206 is performed after the first shower head exhaust step S204 in the above descriptions, the order of performing these steps may be reversed. Alternatively, these steps may be performed simultaneously.

### (Second Processing Gas Supply Step: S208)

After the shower head buffer chamber 232 and the process chamber 201 have been purged, a second processing gas (reaction gas) supply step S208 is performed. In the second processing gas supply step S208, the valve 244d is opened to start supplying a reaction gas (NH₃ gas) into the process chamber 201 via the remote plasma unit 244e and the shower head 230. At this time, the MFC 244c is adjusted so that the flow rate of the reaction gas becomes a predetermined flow rate. The supply flow rate of the reaction gas is, for example, 1,000 to 10,000 sccm.

That is, in the second processing gas supply step S208, the reaction gas supply system 244 supplies the reaction gas, which is one of the processing gases, to the shower head 230 while the substrate 200 is present in the process chamber 201.

The reaction gas in a plasma state is dispersed by the shower head 230 and uniformly supplied onto the substrate 200 in the process chamber 201. The reaction gas reacts with the precursor gas-containing film adsorbed on the substrate 200, and forms a SiN film on the substrate 200.

At this time, the valve 247d of the second inert gas supply system is opened to supply an inert gas (N₂ gas) from the second inert gas supply pipe 247a. The supply flow rate of the inert gas is, for example, 500 to 5,000 sccm. The inert gas may be supplied from the third gas supply pipe 245a of the inert gas supply system 245.

An excess reaction gas and a reaction by-product are introduced into the exhaust buffer chamber 209 from the process chamber 201, flow through the second exhaust pipe 222 of the second gas exhaust system, and are exhausted. Specifically, the second valve 223 in the second gas exhaust system is opened, and the internal pressure of the process chamber 201 is controlled to a predetermined pressure by the APC 224. All the valves of the exhaust system other than the second valve 223 are closed.

After a predetermined time has elapsed since the start of the supply of the reaction gas, the valve 244d is closed to stop the supply of the reaction gas. The supply time of the reaction gas and the carrier gas is, for example, 2 to 20 seconds.

### (Second Shower Head Exhaust Step: S210)

After stopping the supply of the reaction gas, a second shower head exhaust step S210 is performed to remove the reaction gas and the reaction by-product remaining in the shower head buffer chamber 232. This second shower head exhaust step S210 may be performed in the same manner as the already-described first shower head exhaust step S204.

That is, in the second shower head exhaust step S210 as well, the internal temperature of the first exhaust pipe 236 for exhausting the remaining reaction gas and reaction by-product is controlled by operating the first heater 239. Specifically, the first heater 239 is controlled such that the internal temperature of the first exhaust pipe 236 becomes a temperature that does not promote thermal decomposition of the reaction gas and the reaction by-product. In this way, by setting the internal temperature of the first exhaust pipe 236 to a temperature that does not promote thermal decomposition, it is possible to suppress adhesion of the reaction gas and the reaction by-product to the inside the first exhaust pipe 236.

As for the exhaust through the first exhaust pipe 236, the conductance during the exhaust is adjusted by the first valve 237. Specifically, the first valve 237 is controlled so that the inside of the first exhaust pipe 236 has a first conductance. At this time, the APC 238 may be used for control. Details of the first conductance will be described later.

### (Second Processing Space Exhaust Step: S212)

After the shower head buffer chamber 232 is purged, a second processing space exhaust step S212 is performed to remove the reaction gas and the reaction by-products remaining in the process chamber 201. Since this second processing space exhaust step S212 can be performed in the same manner as the already-described first processing space exhaust step S206, the descriptions thereof are omitted here.

### (Determination Step: S214)

The controller 260 determines whether a cycle including the first processing gas supply step S202, the first shower head exhaust step S204, the first processing space exhaust step S206, the second processing gas supply step S208, the second shower head exhaust step S210, and the second processing space exhaust step S212 has been executed a predetermined number of times (n times) at S214. After the cycle is executed the predetermined number of times, a silicon nitride (SiN) film having a desired thickness is formed on the substrate 200.

### (Number of Processing Times Determination Step: S106)

After the film-forming step S104 including the above steps S202 to S214, as shown in FIG. 5, it is determined whether the number of times of execution of the film-forming step S104 has reached a predetermined number of times at S106.

If the number of times of execution of the film-forming step S104 has not reached the predetermined number of times, the processed substrate 200 is taken out, and the process proceeds to a substrate loading/unloading step S108 to start to process a new substrate 200 waiting next. In addition, when the film-forming step S104 has been executed a predetermined number of times, the process proceeds to a substrate unloading step S110 to take out the processed substrate 200 so that the substrate 200 is not present in the chamber 202.

### (Substrate Loading/Unloading Step: S108)

In the substrate loading/unloading step S108, the substrate mounting table 212 is lowered and the substrate 200 is supported on the lift pins 207 protruding from the surface of the substrate mounting table 212. As a result, the substrate 200 is moved from the processing position to the transfer position. Thereafter, the gate valve 205 is opened and the substrate 200 is unloaded from the chamber 202 using a wafer transfer machine.

Thereafter, in the substrate loading/unloading step S108, a new substrate 200 waiting next is loaded into the chamber 202 in the same procedure as the substrate loading/mounting step S102 described above. The substrate is 200 is raised to the processing position in the process chamber 201. The processing temperature and the processing pressure inside the process chamber 201 are set to a predetermined processing temperature and a predetermined processing pressure so that the next film-forming step S104 can be started. Then, the new substrate 200 in the process chamber 201 is subjected to the film-forming step S104 and the number of processing times determination step S106.

### (Substrate Unloading Step: S110)

In the substrate unloading step S110, the processed substrate 200 is taken out from the chamber 202 and unloaded into the transfer chamber in the same procedure as in the substrate loading/unloading step S108. However, unlike the substrate loading/unloading step S108, in the substrate unloading step S110, the new substrate 200 waiting next is not loaded into the chamber 202, whereby the chamber 202 is kept in a state in which the substrate 200 does not exist.

### (Idling Step)

As described above, in the substrate loading/unloading step S108, the process chamber 201 is kept in a state in which the substrate 200 does not exist during a period from the start of loading the processed substrate 200 out of the chamber 202 to the end of loading the new substrate 200 into the chamber 202. Similarly, even after the substrate unloading step S110, the process chamber 201 is kept in a state in which the substrate 200 does not exist during a period from the start of unloading the processed substrate 200 out of the chamber 202 to the start of the substrate loading/placing step S102 for the new substrate 200 and the end of the substrate loading into the chamber 202. Hereinafter, the state in which the substrate 200 is not present in the process chamber 201 and the processing of the next new substrate 200 is awaited will be referred to as an “idling step” or “idling time.”

During the idling time, when processing a new substrate 200, it is desirable to be able to start the processing quickly in order to improve the throughput when processing a plurality of substrates.

Therefore, during the idling time in which the substrate 200 does not exist in the process chamber 201, unlike the series of steps described above, the processing described below is performed.

In the first processing gas supply step S202 and the first shower head exhaust step S204 described above, (a) the precursor gas supply system 243 supplies a precursor gas, which is one of processing gases, to the shower head 230 in a state in which the substrate 200 is present in the process chamber 201, and at least the first valve 237 is controlled so that the inside of the first exhaust pipe 236 has a first conductance in a state in which the first heater 239 is operated.

Furthermore, in the second processing gas supply step S208 and the second shower head exhaust step S210 described above, (a) the reaction gas supply system 244 supplies a reaction gas, which is one of processing gases, to the shower head 230 in a state in which the substrate 200 is present in the process chamber 201, and at least the first valve 237 is controlled so that the inside of the first exhaust pipe 236 has a first conductance in a state in which the first heater 239 is operated.

On the other hand, during the idling time, (b) the inert gas supply system 245 supplies an inert gas, which is one of non-processing gases, to the shower head 230 in a state in which the substrate 200 is not present in the process chamber 201, and at least the first valve 237 is controlled so that the inside of the first exhaust pipe 236 has a second conductance smaller than the first conductance in a state in which the first heater 239 is operated.

The first conductance in the above (a) and the second conductance in the above (b) are not limited to specific magnitudes as long as the magnitude relationship thereof is established, and may be set appropriately through the control of at least the first valve 237.

By executing control as in the above (a) in a state in which the substrate 200 is present in the process chamber 201 and executing control as in the above (b) in a state in which the substrate 200 is not present in the process chamber 201 as described above, it is possible to allow the gas to stay in the first exhaust pipe 236 while operating the first heater 239 in a state in which the substrate 200 is not present in the process chamber 201 (e.g., during the idling time). As a result, it is possible to reduce an amount of temperature drop in the first exhaust pipe 236 during the idling time. Therefore, when processing the next new substrate 200, it is possible to quickly set the temperature in the first exhaust pipe 236 to the temperature for substrate processing, and as a result, it is possible to enhance the throughput when processing a plurality of substrates.

More specifically, the following control is executed as an operation during the idling time.

As already mentioned, the first exhaust pipe 236 includes the first valve 237 which functions as a first exhaust controller. In such a configuration, the opening degree of the first valve 237 in the above (a) is controlled so as to be greater than the opening degree of the first valve 237 in the above (b) in which the inert gas, which is one of the non-processing gases, flows. By controlling the opening degree of the first valve 237 in this manner, it is possible to allow the heated inert gas to stay in the first exhaust pipe 236. This is very desirable to reduce an amount of temperature drop in the first exhaust pipe 236 during the idling time, and to enhance the throughput when processing a plurality of substrates.

More specifically, the process in the above (a) is a cycle process. Substrate processing is performed by, for example, repeating a combination of “first process gas supply step: S202→first shower head exhaust process: S204 (→first process space exhaust step: S206)→second processing gas supply step: S208→second shower head exhaust step: S210 (→second processing space exhaust step: S212).” In other words, the above (a) includes steps S204 and S210 of exhausting the atmosphere in the shower head buffer chamber 232. In such a case, the opening degree of the first valve 237 in the above (a) is the opening degree of the valve in the steps S204 and S210 of exhausting the atmosphere in the shower head buffer chamber 232. The opening degree of the valve is greater than in the case of the above (b). Therefore, even if the heated inert gas is allowed to stay in the first exhaust pipe 236 in the above (b), the exhaust is not delayed in the steps S204 and S210 of exhausting the atmosphere in the shower head buffer chamber 232.

Further, in the above (b), the following control operation may be performed as the control operation for the first valve 237 which functions as a first exhaust controller. For example, in the above (b), when the inert gas, which is one of the non-processing gases, flows through the first exhaust pipe 236, (b-1) the first exhaust pipe 236 is caused to have a predetermined conductance in a state in which the first heater 239 is operated, and (b-2) the first exhaust pipe 236 is caused to have a conductance lower than the predetermined conductance after a predetermined time has elapsed. If the conductance in the first exhaust pipe 236 is controlled according to the elapsed time by controlling the first exhaust controller in this way, it is possible to realize maintaining the internal temperature of the first exhaust pipe 236 by which the inert gas is moved into the first exhaust pipe 236 by, first, increasing the conductance of the first exhaust pipe 236 (that is, allowing the inert gas to flow), and the inert gas stays in the first exhaust pipe 236 by closing the first valve 237 after a predetermined time has elapsed.

More specifically, as the control operation for the first valve 237 in the first exhaust pipe 236, the first valve 237 is opened in the above (b-1), and the opening degree of the first valve 237 in the above (b-2) is set to be smaller than in the case of the above (b-1). The opening degree of the first valve 237 in the above (b-2) may be reduced as compared with the case of the above (b-1), or the first valve 237 may be closed. If the opening degree of the first valve 237 is controlled in this way, it is possible to reliably realize maintaining the internal temperature of the first exhaust pipe 236 by which the inert gas flows through the first exhaust pipe 236 by opening the first valve 237, and the inert gas stays in the first exhaust pipe 236 by reducing the opening degree of the first valve 237 or closing the first valve 237 after a predetermined time has elapsed.

By the way, the chamber 202 of the substrate processing apparatus 100 includes the second gas exhaust system for exhausting the atmosphere in the process chamber 201 in addition to the first gas exhaust system which is the target of the control operation described above. As described above, the second gas exhaust system includes the second exhaust pipe 222 communicating with the process chamber 201. The APC 224 functioning as a second exhaust controller and the second valve 223 are installed in the second exhaust pipe 222.

In such a relationship with the second exhaust pipe 222, the following control operation may be performed for the gas exhaust through the first exhaust pipe 236. For example, at least the first valve 237 in the first exhaust pipe 236 and the APC 224 and the second valve 223 in the second exhaust pipe 222 are controlled such that, when the inert gas, which is one of the non-processing gases, flows through the first exhaust pipe 236, an exhaust amount of gas from the second exhaust pipe 222 in the above (b) is greater than an exhaust amount of gas from the first exhaust pipe 236.

If the exhaust amount from the second exhaust pipe 222 is increased as described above, the flow of the gas from the shower head buffer chamber 232 to the second exhaust pipe 222 increases. This makes it possible to reduce the exhaust amount of the gas from the first exhaust pipe 236. Therefore, it is possible to reduce the amount of temperature drop in the first exhaust pipe 236.

Further, as in the above (a) and (b), the following temperature control may be performed when the gas is exhausted through the first exhaust pipe 236. For example, the output of the first heater 239 in the above (a) is set to be higher than the output in the above (b) in which the inert gas, which is one of the non-processing gases, flows through the first exhaust pipe 236. Since the inert gas does not adhere to the inside of the first exhaust pipe 236, the internal temperature of the first exhaust pipe 236 does not need to be increased unlike the case where the processing gas flows through the first exhaust pipe 236. Therefore, power consumption can be reduced by suppressing the output of the first heater 239 in the case of the above (b) as compared with the case of the above (a).

Furthermore, the temperature control in the first exhaust pipe 236 may be performed as follows. For example, if the temperature measurer 264 capable of measuring the temperature in the first exhaust pipe 236 is installed, in the above (b) in which the inert gas, which is one of the non-processing gases, flows through the first exhaust pipe 236, the operation of the first heater 239 is controlled so that, when the internal temperature of the first exhaust pipe 236 measured by the temperature measurer 264 is lower than a predetermined temperature, the internal temperature of the first exhaust pipe 236 becomes higher than the predetermined temperature.

If the operation of the first heater 239 is controlled in this way, the internal temperature of the first exhaust pipe 236 can be maintained so that the internal temperature of the first exhaust pipe 236 does not fall below the predetermined temperature. Therefore, when processing the next new substrate 200, the internal temperature of the first exhaust pipe 236 can be quickly raised to the temperature for substrate processing. This is very desirable to enhance the throughput when processing a plurality of substrates.

### (Cleaning Step: S112)

After the substrate unloading step S110, the process may proceed to a cleaning step S112 instead of the idling step described above.

In the cleaning step S112, a cleaning process for cleaning the inside of the shower head buffer chamber 232 and a second cleaning process for cleaning the inside of the process chamber 201 are mainly performed.

When the cleaning process on the inside of the shower head buffer chamber 232 is performed, a cleaning gas, which is one of the non-processing gases, is supplied into the shower head buffer chamber 232 by the cleaning gas supply system. Then, by using the flow of the cleaning gas, a cleaning process of removing deposits (reaction by-products, etc.), which adhere to the inside of the shower head buffer chamber 232, particularly the lower surface of the gas guide 235 (the surface facing the dispersion plate 234), the upper surface of the dispersion plate 234, and the like, is performed.

The cleaning gas used in the cleaning process is exhausted from the shower head buffer chamber 232 through the first exhaust pipe 236 by the first gas exhaust system, or is exhausted from the inside of the process chamber 201 through the second exhaust pipe 222 by the second gas exhaust system.

That is, the cleaning gas, which is one of the non-processing gases, is exhausted through the first exhaust pipe 236 also in the cleaning step S112. At this time, the internal temperature of the first exhaust pipe 236 is controlled by operating the first heater 239 for the first exhaust pipe 236. Further, for the exhaust through the first exhaust pipe 236, the conductance during the exhaust is adjusted at least by the first valve 237.

Therefore, the above (b) is also established in the cleaning step S112. Specifically, in the cleaning step S112, (b) the cleaning gas supply system supplies a cleaning gas, which is one of non-processing gases, to the shower head 230 in a state in which the substrate 200 is not present in the process chamber 201, and at least the first valve 237 is controlled such that the inside of the first exhaust pipe 236 has a second conductance smaller than the first conductance in a state in which the first heater 239 is operated.

The first conductance in the above (a) and the second conductance in the above (b) are not limited to specific magnitudes as long as the their magnitude relationship is established, and may be set appropriately through the control of at least the first valve 237.

By executing the control as in the above (a) in the state in which the substrate 200 is present in the process chamber 201 and executing the control as in the above (b) in the state in which the substrate 200 is not present in the process chamber 201 as described above, it is possible to allow a gas to stay in the first exhaust pipe 236 while operating the first heater 239 in the state in which the substrate 200 is not present (e.g., during the cleaning process). As a result, it is possible to reduce an amount of temperature drop inside the first exhaust pipe 236 during the cleaning process. Therefore, after the cleaning step S112 is finished, when processing the next new substrate 200, it is possible that the internal temperature of the first exhaust pipe 236 quickly approaches a temperature for substrate processing, and as a result, it is possible to enhance the throughput when processing a plurality of substrates.

More specifically, the following control is performed as the operation during the cleaning process.

Regarding the internal temperature of the first exhaust pipe 236, the operation of the first heater 239 is controlled so that the internal temperature of the first exhaust pipe 236 in the above (a) is lower than the internal temperature of the first exhaust pipe 236 in the above (b). By controlling the first heater 239 in this way, the internal temperature of the first exhaust pipe 236 in the above (a) can be set to a temperature at which the gas in the first exhaust pipe 236 is not thermally decomposed, and the internal temperature of the first exhaust pipe 236 in the above (b) can be set to a temperature which is higher than the temperature in the above (a) and at which the deposits are thermally decomposed. This makes it possible to remove the cleaning target objects in the first exhaust pipe 236.

In addition, in the cleaning step S112, the cleaning gas can also flow through the second exhaust pipe 222 communicating with the process chamber 201. The APC 224 and the second valve 223, which function as a second exhaust controller, are installed in the second exhaust pipe 222.

In such a relationship between the second exhaust pipe 222 and the first exhaust pipe 236, when the cleaning gas, which is one of the non-processing gases, flows, in the above (b), (b-1) at least the first valve 237 in the first exhaust pipe 236 and the APC 224 and the second valve 223 in the second exhaust pipe 222 are controlled so that the conductance of the first exhaust pipe 236 is lower than the conductance of the second exhaust pipe 222, and (b-2) at least the first valve 237 in the first exhaust pipe 236 and the APC 224 and the second valve 223 in the second exhaust pipe 222 are controlled so that the conductance of the first exhaust pipe 236 is higher than the conductance of the second exhaust pipe 222.

In the above (b-2), the operation of the first heater 239 is controlled so that the internal temperature of the first exhaust pipe 236 becomes higher than the internal temperature of the first exhaust pipe 236 in the above (a).

By such control, it is possible to allow the cleaning gas to flow while setting the internal temperature of the first exhaust pipe 236 in the above (a) to a temperature at which the gas is not thermally decomposed, and setting the internal temperature of the first exhaust pipe 236 in the above (b-2) to a temperature which is higher than the temperature in the above (a) and at which the deposits are thermally decomposed. Accordingly, it is possible to remove the cleaning target objects in the first exhaust pipe 236.

The second heater 225 is installed in the second exhaust pipe 222 in the same manner as the first heater 239 of the first exhaust pipe 236. A heater 213 as a third heater is installed in the substrate support 210 in the chamber 202.

While using them, the following control operation may be performed when the cleaning gas, which is one of the non-processing gases, flows. For example, in the above (b), at least one or both of the first heater 239 and the second heater 225 is controlled so that the internal temperature of the first exhaust pipe 236 is higher than the internal temperature of the second exhaust pipe 222.

In this case, the cleaning gas is heated to the thermal decomposition temperature of the cleaning target object by the heater 213 as the third heater prior to the second exhaust pipe 222. Therefore, in the second heater 225, just unlike the first heater 239, it is not necessary to actively raise the temperature of the cleaning target object to the decomposition temperature. From the above, by suppressing the heating in the second heater 225 through the control operation described above, it is possible to reduce the energy consumption of the entire apparatus.

### (4) Example of System Processing Operation

Next, an example of the system processing operation in the substrate processing system 1000 including the substrate processing apparatus 100 that executes the substrate processing process described above will be described.

As described above, in the substrate processing system 1000, each process module 110 is provided with a plurality of (specifically, for example, two) chambers 202, and the first exhaust pipes 236 extending from the respective chambers 202 are joined by the common exhaust pipe 252.

Specifically, the process module 110a is provided with the chambers 202a and 202b, the process module 110b is provided with the chambers 202c and 202d, the process module 110c is provided with the chambers 202e and 202f, and the process module 110d is provided with the chambers 202g and 202h. In each of the chambers 202a to 202h, the substrate processing process having the series of procedures described above can be executed.

Here, one process module 110 is focused. Although the case of focusing on the process module 110a will be describe as an example, the same applies to other process modules 110b to 110d.

For example, if the number of substrates in a lot to be processed in the process module 110a is an odd number, there may be generated a situation in which the substrate 200 is processed in one chamber 202a while the substrate 200 is not processed in the other chamber 202b. In such a case, if a gas is supplied to both chambers 202a and 202b in the same manner, the gas supply to the chamber 202b that does not perform processing is useless, so that a gas utilization efficiency is lowered and unnecessary film formation may be caused in the chamber 202b that does not perform processing. On the other hand, if a gas is supplied only to the process chamber 202a, the processing conditions (gas flow rate, etc.) are different from those in the case where the gas is supplied to both the chambers 202a and 202b. Thus, the uniformity of processing for each substrate 200 may be degraded. In particular, when the common gas supply pipe 252 is used, if the gas flow rates are different between one chamber 202a and the other chamber 202b, the pressure in one junction pipe 251a is affected by the pressure in the other junction pipe 251b. Thus, a desired pressure may not be obtained. Since this also affects the processing pressure in the process chamber 201, there is a concern that the desired substrate processing cannot be achieved. Therefore, it is desirable to align the processing conditions such as gas flow rates and the like in both chambers 202a and 202b.

Therefore, in the substrate processing system 1000, when a situation in which the substrate 200 is processed in one chamber (hereinafter referred to as “first chamber”) 202a of the plurality of chambers 202a and 202b constituting the process module 110a, and the substrate 200 is not processed in the other chamber (hereinafter referred to as “second chamber”) 202b occurs, the following atmosphere adjustment process is performed in the second chamber 202b.

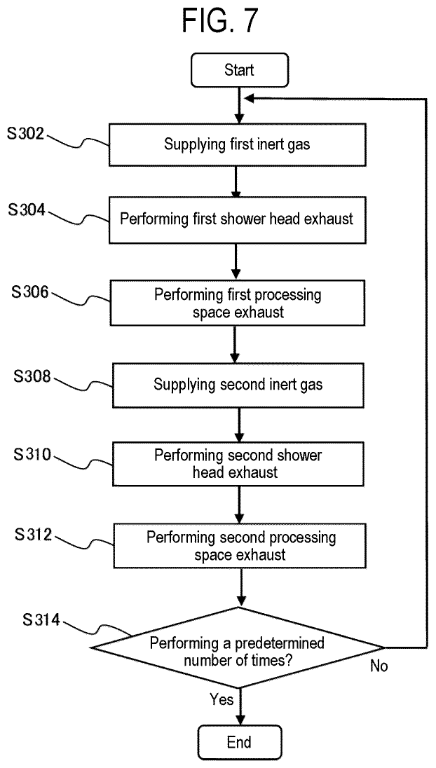

FIG. 7 is a flowchart showing the atmosphere adjustment process according to the present embodiment. It is assumed that the atmosphere adjustment process in the second chamber 202b that does not process the substrate 200 is performed corresponding to the film-forming process (see FIG. 6) in the first chamber 202a.

### (First Inert Gas Supply Step: S302)

In the atmosphere adjustment process, first, a first inert gas supply step S302 is performed. In the first inert gas supply step S302, while the first process gas supply step S202 is being performed in the first chamber 202a, an inert gas is supplied from the third gas supply pipe 245a into the process chamber 201 through the shower head buffer chamber 232 in the second chamber 202b. That is, in the first inert gas supply step S302, the inert gas supply system 245 supplies an inert gas, which is one of the non-processing gases, to the shower head 230 in a state in which the substrate 200 is not present in the process chamber 201.

### (First Shower Head Exhaust Step: S304)

Thereafter, when the first shower head exhaust step S204 is the first chamber 202a performs, a first shower head exhaust step S304 is also performed in the second chamber 202b. The first shower head exhaust step S304 in the second chamber 202b may be performed in the same manner as the first shower head exhaust step S204 in the first chamber 202a.

### (First Processing Space Exhaust Step: S306)

Further, when the first processing space exhaust step S206 is performed in the first chamber 202a, a first processing space exhaust step S306 is also performed in the second chamber 202b also performs. The first processing space exhaust step S306 in the second chamber 202b may be performed in the same manner as the first processing space exhaust step S206 in the first chamber 202a.

### (Second Inert Gas Supply Step: S308)

After the exhaust inside the shower head buffer chamber 232 and the process chamber 201 have been completed, a second inert gas supply step S308) is performed. In the second inert gas supply step S308, while the second processing gas supply step S208 is being performed in the first chamber 202a, an inert gas is supplied from the third gas supply pipe 245a into the process chamber 201 through the shower head buffer chamber 232 in the second chamber 202b. That is, in the second inert gas supply step S308, the inert gas supply system 245 supplies an inert gas, which is one of the non-processing gases, to the shower head 230 in a state in which the substrate 200 is not present in the process chamber 201.

### (Second Shower Head Exhaust Step: S310)

Thereafter, when the second shower head exhaust step S210 is performed in the first chamber 202a, a second shower head exhaust step S310 is also performed in the second chamber 202b. The second shower head exhaust step S310 in the second chamber 202b may be performed in the same manner as the second shower head exhaust step S210 in the first chamber 202a.

### (Second Processing Space Exhaust Step: S312)

Furthermore, when the second processing space exhaust step S212 is performed in the first chamber 202a, a second processing space exhaust step S312 is also performed in the second chamber 202b. The second processing space exhaust step S312 in the second chamber 202b may be performed in the same manner as the second processing space exhaust step S212 in the first chamber 202a.

### (Determination Step: S314)

The controller 260 determines whether a cycle including the above steps S302 to S312 has been performed a predetermined number of times (n times) at S314. When the cycle is performed the predetermined number of times, the film-forming process at S104 in the first chamber 202a is ended. At the same time, in the second chamber 202b as well, the atmosphere adjustment process including the above-described series of procedures is ended.

### (System Operation of First Chamber and Second Chamber)

When the film-forming process is performed in the first chamber 202a and the atmosphere adjustment process is performed in the second chamber 202b as described above, the following control is performed as the operation of the system including these chambers 202a and 202b.

Specifically, while the processing gas is supplied to the first chamber 202a in a state in which the substrate 200 is present, an inert gas, which is one of the non-processing gases, is supplied to the second chamber 202b in a state in which the substrate 200 is not present. In that case, the operation of at least one or both of the first heaters 239a and 239b is controlled so that the temperature of the processing gas in the common exhaust pipe 252 is equal to or higher than a thermal decomposition temperature.

By controlling at least one of the first heaters 239a and 239b in this way, even when the film-forming process is performed in the first chamber 202a and the atmosphere adjustment process is performed in the second chamber 202b, the temperature of the common exhaust pipe 252 can be set to be equal to or higher than a thermal decomposition temperature. Therefore, it becomes possible to prevent unnecessary by-products from adhering to the common exhaust pipe 252.

In addition, the operation of at least one or both of the first heaters 239a and 239b is controlled so that the difference between the internal temperature of the first exhaust pipe 236a of the first chamber 202a and the internal temperature of the first exhaust pipe 236b of the second chamber 202b falls within a predetermined range. As used herein, the expression “temperature difference falls within a predetermined range” means that even if the temperature of the processing gas is lowered due to the temperature difference, the lowered temperature of the processing gas falls within a temperature difference range in which the lowered temperature of the processing gas is not lower than the thermal decomposition temperature. This includes the case where the respective temperatures are the same.

By controlling at least one of the first heater 239a and 239b in this way, even when the processing gas from the first chamber 202a and the non-processing gas from the second chamber 202b join in the common exhaust pipe 252, the temperature of the processing gas does not become lower than the thermal decomposition temperature. Therefore, it becomes possible to prevent unnecessary by-products from adhering to the common exhaust pipe 252. For example, if the temperature of the non-processing gas is lower than the temperature of the processing gas and the temperature difference is greater than or equal to a predetermined value, the non-processing gas may lower the temperature of the processing gas due to the joining in the common exhaust pipe 252. Thus, the processing gas may adhere to the inner wall of the common exhaust pipe 252. In contrast, by controlling the first heaters 239a and 239b as described above, it is possible to prevent such a phenomenon from occurring.

Furthermore, while using the respective first valves 237a and 237b, the difference between the opening degree of the first valve 237a in the first chamber 202a and the opening degree of the first valve 237b in the second chamber 202b is controlled to fall within a predetermined range. As used herein, the expression “difference between the opening degrees falls within a predetermined range” means that the difference in exhaust amount does not exist (falls within a predetermined range) such that the backflow of gases from the common exhaust pipe 252 that joins the flows of the respective gases does not occur. This includes the case where the exhaust amounts are the same.

By controlling the respective first valves 237a and 237b in this way, even when the flows of the respective gases are joined in the common exhaust pipe 252, the backflow of the gases does not occur. For example, when the exhaust amount of the gas exhausted from one chamber 202 is large, that is, when the difference in the exhaust amount exceeds a predetermined range, the gas may flow back into the other chamber 202 from the place where the respective first exhaust pipes 236a and 236b join. In contrast, by keeping the difference between the respective exhaust amounts within the predetermined range, it is possible to prevent the backflow of the gas.

After the atmosphere adjustment process in the second chamber 202b, for example, when starting the substrate processing for a new lot in the process module 110a, a situation in which the substrates 200 are loaded into the first chamber 202a and the second chamber 202b may occur. In such a case, the following control is performed as the operation of the system including the chambers 202a and 202b.

Specifically, when the substrates 200 are loaded into the first chamber 202a and the second chamber 202b, the operation of at least one or both of the first heaters 239a and 239b is controlled such that the difference between the internal temperature of the first exhaust pipe 236a and the internal temperature of the first exhaust pipe 236b falls within a predetermined range. As used herein, the expression “difference between the temperatures falls within a predetermined range” means that the lower temperature falls within a temperature difference range in which the lower temperature can quickly (i.e., within a preset allowable time) approach the internal temperature of the first exhaust pipe 236 for substrate processing. This includes the case where the respective temperatures are the same.

It is more desirable to control the respective first heater 239a and 239b simultaneously. By doing so, even when the substrates 200 are loaded into the first chamber 202a and the second chamber 202b, the internal temperatures of the first exhaust pipes 236a and 236b can approach the temperature for substrate processing at the same time. For example, if the temperature of the first exhaust pipe 236 is only low, it is necessary to secure the time for the temperature to rise. However, by controlling the first heaters 239a and 239b as described above, it is possible to prevent such a phenomenon from occurring. As a result, it is possible to increase the throughput during substrate processing.

Further, if the difference between the temperature in the first exhaust pipe 236a and the temperature in the first exhaust pipe 236b is equal to or greater than a predetermined value, the operation of at least one or both of the first heaters 239a and 239b may be controlled so that the internal temperature of the first exhaust pipe 236b approaches the internal temperature of the first exhaust pipe 236a. As used herein, the expression “temperature difference equal to or greater than a predetermined value” means that there occurs a temperature difference equal to or greater than a predetermined value which is set to determine whether the temperature difference falls within the above-described predetermined range.

By controlling the respective first heaters 239a and 239b in this way, when the substrates 200 are loaded into the first chamber 202a and the second chamber 202b, feedback control can be performed to ensure that the temperature difference between the internal temperatures of the first exhaust pipes 236a and 236b falls within a predetermined range. This is very desirable to increase the throughput during substrate processing.

### (5) Effects of the Present Embodiment

According to the present embodiment, one or more of the following effects may be obtained.

(A) According to the present embodiment, control is executed as in the above (a) when the substrate 200 is present in the process chamber 201, and control is executed as in the above (b) when the substrate 200 is not present in the process chamber 201, so that it becomes possible to allow the gas to stay in the first exhaust pipe 236 while operating the first heater 239 in the state in which the substrate 200 is not present (e.g., during the idling time or cleaning time). Accordingly, it is possible to reduce the amount of temperature drop in the first exhaust pipe 236 in the state in which the substrate 200 is not present. Therefore, when processing the next new substrate 200, it is possible to quickly set the internal temperature of the first exhaust pipe 236 to the temperature for substrate processing, and as a result, it is possible to enhance the throughput when processing a plurality of substrates.

(B) According to the present embodiment, in the above (a), the first heater 239 is controlled such that the internal temperature of the first exhaust pipe 236 becomes a temperature at which the thermal decomposition of the precursor gas is not promoted. This makes it possible to suppress adhesion of the precursor gas to the inside of the first exhaust pipe 236.

(C) According to the present embodiment, the opening degree of the first valve 237 in the above (a) is controlled to be larger than the opening degree of the first valve 237 in the above (b) in which the inert gas, which is one of the non-processing gases, flows. Accordingly, the heated inert gas is allowed to stay in the first exhaust pipe 236. This is very desirable to reduce the amount of temperature drop in the first exhaust pipe 236, and to enhance the throughput when processing a plurality of substrates.

(D) According to the present embodiment, in the above (a), the steps S204 and S210 of exhausting the atmosphere in the shower head buffer chamber 232 are included, and the opening degree of the first valve 237 in the above (a) is the valve opening degree in the steps S204 and S210 of exhausting the atmosphere in the shower head buffer chamber 232. Therefore, even if the heated inert gas is allowed to stay in the first exhaust pipe 236 in the above (b), the exhaust in the steps S204 and S210 of exhausting the atmosphere in the shower head buffer chamber 232 is not delayed.

(E) According to the present embodiment, in the above (b), (b-1) the first exhaust pipe 236 is caused to have a predetermined conductance in a state in which the first heater 239 is operated, and (b-2) the first exhaust pipe 236 is caused to have a conductance lower than the predetermined conductance after a predetermined time has elapsed. Therefore, the internal temperature of the first exhaust pipe 236 can be maintained by firstly increasing the conductance of the first exhaust pipe 236 (that is, allowing the inert gas to flow) so that the inert gas moves through the first exhaust pipe 236, and then closing the first valve 237 after a predetermined time has elapsed so that the inert gas stays in the first exhaust pipe 236.

(F) According to the present embodiment, the first valve 237 is opened in the above (b-1), and the opening degree of the first valve 237 in the above (b-2) is set to be smaller than in the case of the above (b-1). Therefore, the internal temperature of the first exhaust pipe 236 can be reliably maintained by firstly opening the first valve 237 so that the inert gas flows through the first exhaust pipe 236, and then reducing the opening degree of the first valve 237 or closing the first valve 237 after a predetermined time has elapsed so that the inert gas stays in the first exhaust pipe 236.

(G) According to the present embodiment, at least the first valve 237, the APC 224 and the second valve 223 are controlled such that, when the inert gas, which is one of the non-processing gases, flows through the first exhaust pipe 236, the exhaust amount from the second exhaust pipe 222 in the above (b) is greater than the exhaust amount from the first exhaust pipe 236. If the exhaust amount from the second exhaust pipe 222 is increased as described above, the gas flow from the shower head buffer chamber 232 to the second exhaust pipe 222 increases. This makes it possible to reduce the exhaust amount of the gas from the first exhaust pipe 236. Therefore, it is possible to reduce the amount of temperature drop in the first exhaust pipe 236.

(H) According to the present embodiment, the first heater 239 is controlled so that the output of the first heater 239 in the above (a) becomes higher than the output of the first heater 239 in the above (b). Since the inert gas, which is one of the non-processing gases, does not adhere to the inside of the first exhaust pipe 236, the internal temperature of the first exhaust pipe 236 does not need to be increased during the flow of the inert gas unlike the case where the processing gas flows through the first exhaust pipe 236. Therefore, power consumption can be reduced by suppressing the output of the first heater 239 in the case of the above (b) as compared with the case of the above (a).

(I) According to the present embodiment, if the temperature measurer 264 capable of measuring the temperature in the first exhaust pipe 236 is installed, in the above (b) in which the inert gas, which is one of the non-processing gases, flows through the first exhaust pipe 236, the first heater 239 is controlled such that, when the internal temperature of the first exhaust pipe 236 measured by the temperature measurer 264 is lower than a predetermined temperature, the internal temperature of the first exhaust pipe 236 becomes higher than the predetermined temperature. Therefore, the internal temperature of the first exhaust pipe 236 can be maintained so that the internal temperature of the first exhaust pipe 236 does not fall below the predetermined temperature. Therefore, when processing the next new substrate 200, it is possible to quickly raise the internal temperature of the first exhaust pipe 236 to the temperature for substrate processing and this is very desirable to enhance the throughput when processing a plurality of substrates.

(J) According to the present embodiment, when the processing gas is supplied to the first chamber 202a in a state in which the substrate 200 is present and the inert gas, which is one of the non-processing gases, is supplied to the second chamber 202b in a state in which the substrate 200 is not present, at least one of the first heaters 239a and 239b is controlled so that the temperature of the processing gas in the common exhaust pipe 252 is equal to or higher than a thermal decomposition temperature. Therefore, the temperature of the common exhaust pipe 252 can be set to be equal to or higher than a thermal decomposition temperature. This makes it possible to prevent unnecessary by-products from adhering to the common exhaust pipe 252.

(K) According to the present embodiment, at least one of the first heaters 239a and 239b is controlled so that, when the substrates 200 are loaded into the first chamber 202a and the second chamber 202b, the difference between the internal temperature of the first exhaust pipe 236a and the internal temperature of the first exhaust pipe 236b falls within a predetermined range. Therefore, the internal temperatures of the first exhaust pipes 236 can approach the temperature for substrate processing at the same time. As a result, it is possible to enhance the throughput during substrate processing.

(L) According to the present embodiment, if the difference between the internal temperature of the first exhaust pipe 236a and the internal temperature of the first exhaust pipe 236b is equal to or greater than a predetermined value when loading the substrates 200 into the first chamber 202a and the second chamber 202b, at least one of the first heaters 239a and 239b is controlled so that the internal temperature of the first exhaust pipe 236b approaches the temperature in the first exhaust pipe 236a. Therefore, feedback control is performed to ensure that the temperature difference between the internal temperatures of the respective first exhaust pipes falls within a predetermined range. This is very desirable to increase the throughput during substrate processing.

(M) According to the present embodiment, when the processing gas is supplied to the first chamber 202a in a state in which the substrate 200 is present, and the inert gas, which is one of the non-processing gases, is supplied to the second chamber 202b in a state in which the substrate 200 is not present, at least one of the first heaters 239a and 239b is controlled so that the difference between the internal temperature of the first exhaust pipe 236a and the internal temperature of the first exhaust pipe 236b falls within a predetermined range. Therefore, even when the processing gas from the first chamber 202a and the non-processing gas from the second chamber 202b join in the common exhaust pipe 252, the temperature of the processing gas does not drop below the thermal decomposition temperature. This makes it possible to prevent unnecessary adhesion of by-products and the like to the common exhaust pipe 252.

(N) According to the present embodiment, when the cleaning gas, which is one of the non-processing gases, is supplied, the operation of the first heater 239 is controlled so that the internal temperature of the first exhaust pipe 236 in the above (a) is lower than the internal temperature of the first exhaust pipe 236 in the above (b). Therefore, in the above (a), the internal temperature of the first exhaust pipe 236 can be set to a temperature at which the gas is not thermally decomposed, and in the above (b), the internal temperature of the first exhaust pipe 236 can be set to a temperature higher than that in the above (a), at which the deposits are thermally decomposed. This makes it possible to remove the cleaning target object in the first exhaust pipe 236.

(O) According to the present embodiment, in the above (b), (b-1) at least the first valve 237, the APC 224, and the second valve 223 are controlled so that the conductance of the first exhaust pipe 236 is lower than the conductance of the second exhaust pipe 222, and (b-2) at least the first valve 237, the APC 224, and the second valve 223 are controlled so that the conductance of the first exhaust pipe 236 is higher than the conductance of the second exhaust pipe 222. In addition, in the above (b-2), the operation of the first heater 239 is controlled so that the internal temperature of the first exhaust pipe 236 is higher than the internal temperature of the first exhaust pipe 236 in the above (a). Therefore, in the above (a), the internal temperature of the first exhaust pipe 236 can be set to a temperature at which the gas is not thermally decomposed, and in the above (b-2), the cleaning can be allowed to flow in a state in which the internal temperature of the first exhaust pipe 236 is set to a temperature higher than that in the above (a), at which the deposits are thermally decomposed. This makes it possible to remove the cleaning target objects in the first exhaust pipe 236.

(P) According to the present embodiment, in the above (b), when the cleaning gas, which is one of the non-processing gases, flows, at least one selected from the group of the first heater 239 and the second heater 225 is controlled so that the internal temperature of the first exhaust pipe 236 is higher than the internal temperature of the second exhaust pipe 222. Therefore, prior to the second exhaust pipe 222, the temperature of the cleaning gas is raised to the thermal decomposition temperature of the cleaning target object by the heater 213 as a third heater. It is not necessary for the second heater 225 to actively heat the cleaning gas to the thermal decomposition temperature of the cleaning target object. By suppressing the heating in the second heater 225 in this way, it is possible to reduce the energy consumption of the entire apparatus.

(Q) According to the present embodiment, when the processing gas is supplied to the first chamber 202a in a state in which the substrate 200 is present, and the inert gas or cleaning gas is supplied as a non-processing gas to the second chamber 202b in a state in which the substrate 200 is not present, the first valve 237 is used to control the difference between the opening degree of the first valve 237a and the opening degree of the first valve 237b to fall within a predetermined range. Therefore, even when the gas flows from the first chamber 202a and the second chamber 202b are joined at the common exhaust pipe 252, it is possible to prevent the backflow of the gas from occurring.

### (6) Other Embodiments of the Present Disclosure

Although the embodiment of the present disclosure has been specifically described above, the present disclosure is not limited to the above-described embodiment, and may be variously modified without departing from the gist thereof.

For example, in the above-described embodiment, the case where, in the film-forming process performed by the substrate processing apparatus 100, the Si₂Cl₆ gas is used as the precursor gas (first processing gas), the NH₃ gas is used as the reaction gas (second processing gas), and the SiN film is formed on the substrate 200 by alternately supplying the Si₂Cl₆ gas and the NH₃ gas has been described by way of example. However, the present disclosure is not limited thereto. That is, the processing gases used for the film-forming process are not limited to the Si₂Cl₆ gas and the NH₃ gas. Other types of thin films may be formed by using other types of gases. Furthermore, even when three or more types of processing gases are used, the present disclosure can be applied as long as the film-forming process is performed by alternately supplying these gases.

Further, for example, in the above-described embodiment, the film-forming process is described as an example of the process performed by the substrate processing apparatus 100. However, the present disclosure is not limited thereto. That is, in addition to the film-forming process, the process performed by the substrate processing apparatus 100 may be a process for forming an oxide film or a nitride film, or may be a process for forming a film containing a metal. Further, regardless of the specific content of the substrate processing, the present disclosure may be suitably applied not only to the film-forming process but also to other substrate processing such as annealing, oxidation, nitridation, diffusion, lithography, and the like. Moreover, the present disclosure can be suitably applied to other substrate processing apparatuses, for example, an annealing apparatus, an oxidation apparatus, a nitriding apparatus, an exposure apparatus, a coating apparatus, a drying apparatus, a heating apparatus, a plasma processing apparatus using plasma, and the like. Further, the present disclosure may be applied to a combination of these apparatuses. A part of the configurations of one embodiment can be replaced with the configuration of another embodiment, and the configuration of another embodiment can be added to the configuration of one embodiment. In addition, a part of the configuration of each embodiment can be added with another configuration, deleted, or replaced.

In this specification, the expression of a numerical range such as “1 to 2000 Pa” means that the lower limit and the upper limit are included in the range. Therefore, for example, “1 to 2,000 Pa” means “1 Pa or more and 2,000 Pa or less”. The same applies to other numerical ranges.

According to the present disclosure in some embodiments, it is possible to enhance the throughput when processing a plurality of substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
at least one chamber including a process chamber that is capable of processing a substrate and a shower head arranged in an upstream of the process chamber;
a gas supplier that is capable of supplying a gas into the process chamber via the shower head;
a first exhaust pipe communicating with the shower head;
a second exhaust pipe communicating with the process chamber;
a first exhaust controller installed in the first exhaust pipe;
a first heater installed in the first exhaust pipe; and
a controller configured to be capable of:
(a) controlling the gas supplier so as to supply a processing gas as the gas to the shower head in a state in which the substrate is present in the process chamber and the first exhaust controller such that an inside of the first exhaust pipe has a first conductance in a state in which the first heater is operated, and
(b) controlling the gas supplier so as to supply a non-processing gas as the gas to the shower head in a state in which the substrate is not present in the process chamber and the first exhaust controller such that the inside of the first exhaust pipe has a second conductance smaller than the first conductance in a state in which the first heater is operated.

2. The substrate processing apparatus of claim 1, wherein in (a), the controller controls the first heater such that a temperature in the first exhaust pipe becomes a temperature that does not promote thermal decomposition of the processing gas.

3. The substrate processing apparatus of claim 1, wherein the first exhaust controller includes a valve,
wherein the non-processing gas is an inert gas, and
wherein an opening degree of the valve in (a) is controlled so as to be greater than an opening degree of the valve in (b).

4. The substrate processing apparatus of claim 3, wherein (a) includes exhausting an atmosphere in the shower head, and
wherein the opening degree of the valve in (a) is an opening degree of the valve in the act of exhausting the atmosphere in the shower head.

5. The substrate processing apparatus of claim 1, wherein the non-processing gas is an inert gas, and
wherein in (b), the controller controls the first exhaust controller such that:
(b-1) the inside of the first exhaust pipe has a predetermined conductance in a state in which the first heater is operated; and
(b-2) the inside of the first exhaust pipe has a conductance lower than the predetermined conductance after a predetermined time has elapsed.

6. The substrate processing apparatus of claim 5, wherein the first exhaust controller includes a valve, and
wherein the controller is configured to control the valve such that:
the valve is opened in (b-1); and
an opening degree of the valve in (b-2) becomes smaller than an opening degree of the valve in (b-1).

7. The substrate processing apparatus of claim 1, further comprising a second exhaust controller installed in the second exhaust pipe,
wherein the non-processing gas is an inert gas, and
wherein the controller controls the first exhaust controller and the second exhaust controller such that an exhaust amount from the second exhaust pipe in (b) is larger than an exhaust amount from the first exhaust pipe.

8. The substrate processing apparatus of claim 1, wherein the non-processing gas is an inert gas, and
wherein the controller controls the first heater such that an output of the first heater in (a) becomes higher than an output of the first heater in (b).

9. The substrate processing apparatus of claim 1, further comprising a temperature measurer that is capable of measuring an internal temperature of the first exhaust pipe,
wherein the non-processing gas is an inert gas, and
wherein, when the internal temperature of the first exhaust pipe is lower than a predetermined temperature in (b), the controller controls the first heater such that the internal temperature of the first exhaust pipe becomes higher than the predetermined temperature.

10. The substrate processing apparatus of claim 1, wherein the at least one chamber is installed in a plural number,
wherein the apparatus further comprise a common exhaust pipe for joining the first exhaust pipe of the plurality of chambers,
wherein the non-processing gas is an inert gas, and
wherein the controller controls the gas supplier so as to supply the processing gas into a first chamber of the plurality of chambers in a state in which the substrate is present and supply the non-processing gas into a second chamber of the plurality of chambers in a state in which the substrate is not present, and controls at least one selected from the group of the first heater of the first chamber and the first heater of the second chamber such that a temperature of the processing gas in the common exhaust pipe is equal to or higher than a thermal decomposition temperature.

11. The substrate processing apparatus of claim 1, wherein the at least one chamber is installed in a plural number, and
wherein, when loading the substrate into a first chamber of the plurality of chambers and a second chamber of the plurality of chambers, the controller controls at least one selected from the group of the first heater of the first chamber and the first heater of the second chamber such that a difference between an internal temperature of the first exhaust pipe of the first chamber and an internal temperature of the first exhaust pipe of the second chamber falls within a predetermined range.

12. The substrate processing apparatus of claim 1, wherein the at least one chamber is installed in a plural number, and
wherein, when loading the substrate into a first chamber of the plurality of chambers and a second chamber of the plurality of chambers, if a difference between an internal temperature of the first exhaust pipe of the first chamber and an internal temperature of the first exhaust pipe of the second chamber is equal to or greater than a predetermined value, the controller controls at least one selected from the group of the first heater of the first chamber and the first heater of the second chamber such that an internal temperature of the first exhaust pipe of the second chamber approaches an internal temperature of the first exhaust pipe of the first chamber.

13. The substrate processing apparatus of claim 1, wherein the at least one chamber is installed in a plural number,
wherein the non-processing gas is an inert gas, and
wherein the controller controls the gas supplier so as to supply the processing gas into a first chamber of the plurality of chambers in a state in which the substrate is present and supply the non-processing gas into a second chamber of the plurality of chambers in a state in which the substrate is not present, and controls at least one selected from the group of the first heater of the first chamber and the first heater of the second chamber such that a difference between the internal temperature of the first exhaust pipe of the first chamber and an internal temperature of the first exhaust pipe of the second chamber falls within a predetermined range.

14. The substrate processing apparatus of claim 1, wherein the non-processing gas is a cleaning gas, and
wherein the controller controls the first heater such that an internal temperature of the first exhaust pipe in (a) is lower than an internal temperature of the first exhaust pipe in (b).

15. The substrate processing apparatus of claim 1, further comprising a second exhaust controller installed in the second exhaust pipe,
wherein the non-processing gas is a cleaning gas,
wherein in (b), the controller is configured to:
(b-1) control the first exhaust controller and the second exhaust controller such that a conductance of the first exhaust pipe is lower than a conductance of the second exhaust pipe; and
(b-2) control the first exhaust controller and the second exhaust controller such that the conductance of the first exhaust pipe is higher than the conductance of the second exhaust pipe, and
wherein the controller, in (b-2), is configured to control the first heater such that the internal temperature of the first exhaust pipe is higher than the internal temperature of the first exhaust pipe in (a).

16. The substrate processing apparatus of claim 1, further comprising:
a second heater installed in the second exhaust pipe;
a substrate support installed in the process chamber to support the substrate; and
a third heater installed in the substrate support,
wherein the non-processing gas is a cleaning gas, and
wherein the controller is configured to, in (b), control at least one selected from the group of the first heater and the second heater such that the internal temperature of the first exhaust pipe is higher than the internal temperature of the second exhaust pipe.

17. The substrate processing apparatus of claim 2, wherein the at least one chamber is installed in a plural number,
wherein the apparatus further comprise a valve installed in the first exhaust controller of each of the plurality of chambers, and
wherein the controller is configured to control the gas supplier so as to supply the processing gas in a state in which the substrate is present in a first chamber of the plurality of chambers and supply the non-processing gas in a state in which the substrate is not present in a second chamber of the plurality of chambers, and control the valve such that a difference between an opening degree of the valve of the first chamber and an opening degree of the valve of the second chamber falls within a predetermined range.

18. A method of processing a substrate, comprising:
(a) supplying a processing gas to a shower head installed in an upstream of a process chamber in a state in which a substrate is present in the process chamber, and operating a first heater installed in a first exhaust pipe in a state in which an inside of the first exhaust pipe has a first conductance by a first exhaust controller installed in the first exhaust pipe connected to the shower head; and
(b) supplying a non-processing gas to the shower head in a state in which the substrate is not present in the process chamber, and operating the first heater installed in the first exhaust pipe in a state in which the inside of the first exhaust pipe has a second conductance smaller than the first conductance by the first exhaust controller.

19. A method of manufacturing a semiconductor device by the substrate processing method of claim 18.

20. A non-transitory computer-readable recording medium storing a program that causes, by a computer, a substrate processing apparatus to perform a process comprising:
(a) supplying a processing gas to a shower head installed in an upstream of a process chamber in a state in which a substrate is present in the process chamber, and operating a first heater installed in a first exhaust pipe in a state in which an inside of the first exhaust pipe has a first conductance by a first exhaust controller installed in the first exhaust pipe connected to the shower head; and
(b) supplying a non-processing gas to the shower head in a state in which the substrate is not present in the process chamber, and operating the first heater installed in the first exhaust pipe in a state in which the inside of the first exhaust pipe has a second conductance smaller than the first conductance by the first exhaust controller.
